(19) United States
(12) Patent Application Publication
(10) Pub. No.: US 2014/0138633 A1
(43) Pub. Date: May 22, 2014

(54) ORGANIC LIGHT-EMITTING DEVICE

(71) Applicant: SAMSUNG DISPLAY CO., LTD., Yongin-City (KR)

(72) Inventors: Hye-Jin Jung, Yongin-City (KR); Seok-Hwan Hwang, Yongin-City (KR); Young-Kook Kim, Yongin-City (KR); Jin-O Lim, Yongin-City (KR); Sang-Hyun Han, Yongin-City (KR); Eun-Jae Jeong, Yongin-City (KR); Soo-Yon Kim, Yongin-City (KR); Jun-Ha Park, Yongin-City (KR); Eun-Young Lee, Yongin-City (KR); Jong-Hyuk Lee, Yongin-City (KR)

(73) Assignee: SAMSUNG DISPLAY CO., LTD., Yongin-City (KR)

(21) Appl. No.: 13/804,196

(22) Filed: Mar. 14, 2013

(30) Foreign Application Priority Data
Nov. 16, 2012 (KR) 10-2012-0130507

(51) Int. Cl. H01L 51/00

(52) U.S. Cl. CPC H01L 51/0054; H01L 51/0062; H01L 51/0067; H01L 51/0072; H01L 51/0077; H01L 51/0094
USPC 257/40

(57) ABSTRACT

Provided is an organic light-emitting device including a compound represented by Formula 1 below:

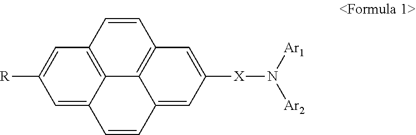

wherein description of Formula 1 above is specified in the detailed description.

### CLAIM OF PRIORITY

This application makes reference to, incorporates the same herein, and claims all benefits accruing under 35 U.S.C. §119 from an application for ORGANIC LIGHT-EMITTING DEVICE earlier filed in the Korean Intellectual Property Office on 16 Nov. 2012 and there duly assigned Serial No. 10-2012-0130507.

### BACKGROUND OF THE INVENTION

1. Field of the Invention

The present invention relates to an organic light-emitting device including a compound of Formula 1.

2. Description of the Related Art

Organic light-emitting devices (OLEDs), which are self-emitting devices, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. The HTL, the EML, and the ETL are organic thin films formed of organic compounds.

An operating principle of an OLED having the above-described structure is as follows.

When a voltage is applied between the anode and the cathode, holes injected from the anode move to the EML via the HTL, and electrons injected from the cathode move to the EML via the ETL. The holes and electrons (carriers) recombine in the organic EML to generate excitons. When the excitons drop from an excited state to a ground state, light is emitted.

There is an ongoing demand for a material having improved electrical stability, high charge-transfer or emission capability, a high glass transition temperature, and capable of preventing crystallization, relative to existing unimolecular materials.

### SUMMARY OF THE INVENTION

The present invention provides an organic light-emitting device with high color purity, high efficiency, and long lifetime by including a compound according to an embodiment of the present invention as an organic light-emitting material.

According to an aspect of the present invention, there is provided an organic light-emitting device (OLED) including a first electrode; a second electrode; and an organic layer disposed between the first electrode and the second electrode, wherein the organic layer includes an emission layer and/or a hole transport layer, and the emission layer and/or hole transport layer include the compound of Formula 1 described below:

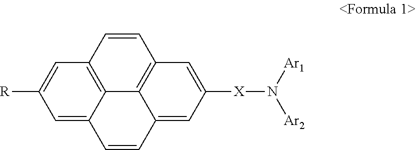

In Formula 1,

R may be —CN, a halogen atom, —SiR₁R₂R₃, —OR₁, —SR₁, —PR₁R₂, a substituted or unsubstituted C1-C60 alkyl group, a substituted or unsubstituted C3-C60 heteroaryl group, a substituted or unsubstituted C6-C60 aryl group, or a substituted or unsubstituted C6-C60 condensed polycyclic group;

R₁ to R₃ may be each independently a substituted or unsubstituted C1-C30 alkyl group, a substituted or unsubstituted C6-C30 aryl group, a substituted or unsubstituted C6-C30 condensed polycyclic group;

Ar₁ to Ar₂ may be each independently a substituted or unsubstituted C5-C60 aryl group, a substituted or unsubstituted C4-C60 heteroaryl group, or a substituted or unsubstituted C6-C60 condensed polycyclic group; and

X may be a direct bond, a substituted or unsubstituted C5-C60 arylene group, a substituted or unsubstituted C4-C60 heteroarylene group, a substituted or unsubstituted C6-C60 condensed polycyclic group, or a divalent linking group formed by linking at least two of the arylene group, the heteroarylene group, and the condensed polycyclic group.

According to another aspect of the present invention, there is provided a flat panel display device including the above-described organic light-emitting device, wherein the first electrode of the organic light-emitting device is electrically connected to a source electrode or a drain electrode of a thin-film transistor.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view of a structure of an organic light-emitting device according to an embodiment of the present invention.

### DETAILED DESCRIPTION OF THE INVENTION

As used herein, the term “and/or” includes any and all combinations of one or more of the associated listed items. Expressions such as “at least one of,” when preceding a list of elements, modify the entire list of elements and do not modify the individual elements of the list.
An aspect of the present invention provides an organic light-emitting device (OLED) including a first electrode; a second electrode; and an organic layer disposed between the first electrode and the second electrode, wherein the organic layer includes an emission layer and/or a hole transport layer, and the emission layer and/or the hole transport layer include the compound of Formula 1 described above.

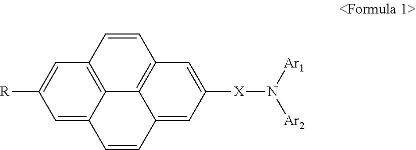

In Formula 1,

R may be —CN, a halogen atom, —SiR₁R₂R₃, —OR₁, —SR₁, —PR₁R₂, a substituted or unsubstituted C1-C60 alkyl group, a substituted or unsubstituted C3-C60 heteroaryl group, a substituted or unsubstituted C6-C60 aryl group, or a substituted or unsubstituted C6-C60 condensed polycyclic group;

R₁ to R₃ may be each independently a substituted or unsubstituted C1-C30 alkyl group, a substituted or unsubstituted C6-C30 aryl group, a substituted or unsubstituted C6-C30 condensed polycyclic group;

Ar₁ to Ar₂ may be each independently a substituted or unsubstituted C5-C60 aryl group, a substituted or unsubstituted C4-C60 heteroaryl group, or a substituted or unsubstituted C6-C60 condensed polycyclic group; and

X may be a direct bond, a substituted or unsubstituted C5-C60 arylene group, a substituted or unsubstituted C4-C60 heteroarylene group, a substituted or unsubstituted C6-C60 condensed polycyclic group, or a divalent linking group formed by linking at least two of the arylene group, the heteroarylene group, and the condensed polycyclic group.

The compound of Formula 1 according to an embodiment of the present invention is suitable as a blue dopant or a hole transporting material, and an OLED including the compound of Formula 1 may have characteristics such as high efficiency, long lifetime, and the like.

The compound of Formula 1 will now be described in detail.

In some embodiments, in Formula 1, R may be one of the groups represented by Formulae 2a to 2f below:

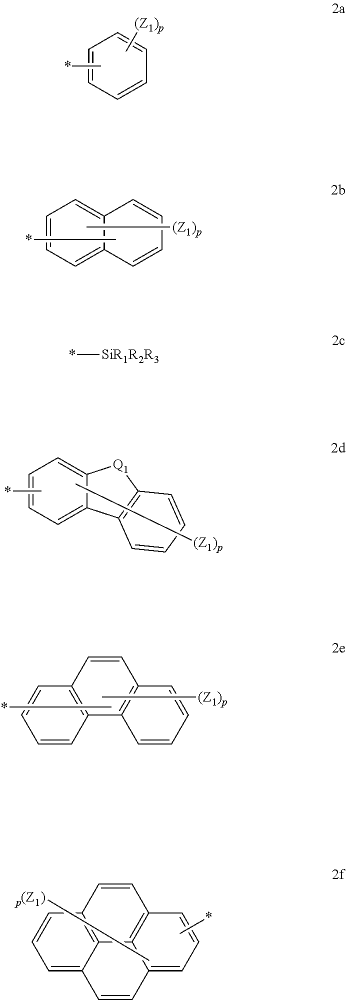

In Formulae 2a to 2f,

Q₁ may be a linking group represented by —C(R₃₀)(R₃₁)—, —N(R₃₂)—, or —Si(R₃₃)(R₃₄)—;

Z₁ and R₃₀ to R₃₄ may be each independently, a hydrogen atom, a deuterium atom, a substituted or unsubstituted C1-C20 alkyl group, a substituted or unsubstituted C5-C20 aryl group, a substituted or unsubstituted C3-C20 heteroaryl group, or a substituted or unsubstituted C6-C20 condensed polycyclic group, a halogen group, a cyano group, a nitro group, a hydroxyl group, or a carboxyl group;

R₁ to R₃ may be each independently a substituted or unsubstituted C1-C30 alkyl group, a substituted or unsubstituted C6-C30 aryl group, or a substituted, or unsubstituted C6-C30 condensed polycyclic group;

p is an integer from 1 to 9; and * indicates a binding site.

In some other embodiments, in Formula 2d, R₃₀ and R₃₁ may be selectively linked to each other and form a ring.

In some other embodiments, in Formula 1, Ar₁ and Ar₂ may be each independently one of the groups represented by Formulae 3a to 3e below:

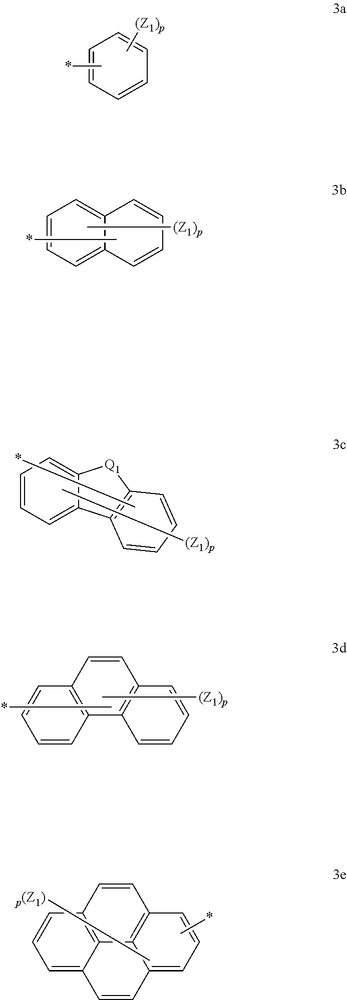

In Formulae 3a to 3e,

Q₂ may be a linking group represented by —C(R₃₀)(R₃₁)—, —N(R₃₂)—, or —Si(R₃₃)(R₃₄)—;

Z₁, R₃₀ to R₃₄ may be each independently, a hydrogen atom, a deuterium atom, —SiR₁R₂R₃, a substituted or unsubstituted C1-C20 alkyl group, a substituted or unsubstituted C5-C20 aryl group, a substituted or unsubstituted C3-C20 heteroaryl group, a substituted or unsubstituted C6-C20 condensed polycyclic group, a halogen group, a cyano group, a nitro group, a hydroxyl group, or a carboxyl group;

R₁ to R₃ may be each independently a substituted or unsubstituted C1-C30 alkyl group, a substituted or unsubstituted C6-C30 aryl group, or a substituted, or unsubstituted C6-C30 condensed polycyclic group;

p is an integer from 1 to 9; and * indicates a binding site.

In some other embodiments, in Formula 3c, R₃₀ and R₃₁ may be selectively linked to each other and form a ring.

In some other embodiments, in Formula 1, X may be a direct bond or one of the groups represented by Formulae 4a to 4d below:

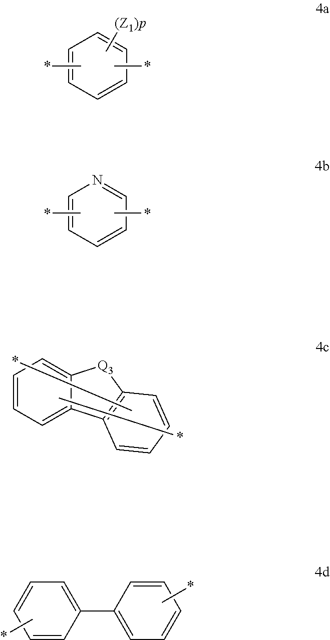

In Formulae 4a to 4c,

Q₃ may be a linking group represented by —C(R₃₀)(R₃₁)—, —S—, or —O—;

Z₁, R₃₀, and R₃₁ may be each independently, a hydrogen atom, a deuterium atom, a substituted or unsubstituted C1-C20 alkyl group, a substituted or unsubstituted C5-C20 aryl group, a substituted or unsubstituted C3-C20 heteroaryl group, a substituted or unsubstituted C6-C20 condensed polycyclic group, a halogen group, a cyano group, a nitro group, a hydroxyl group, or a carboxyl group;

p is an integer from 1 to 4; and * indicates a binding site.

Hereinafter, substituents described with reference to the formulae will now be described in detail. (In this regard, the numbers of carbons in substituents are presented only for illustrative purposes and do not limit the characteristics of the substituents, and substituents that are not defined in the present application are defined as substituents generally known to one of ordinary skill in the art).

The unsubstituted C1-C60 alkyl group may be linear or branched. Non-limiting examples of the unsubstituted C1-C60 alkyl group are methyl, ethyl, propyl, isobutyl, sec-butyl, pentyl, iso-amyl, hexyl, heptyl, octyl, nonanyl, and dodecyl. At least one hydrogen atom of the unsubstituted C1-C60 alkyl group may be substituted with a deuterium atom, a halogen atom, a hydroxyl group, a nitro group, a cyano group, an amino group, an amidino group, a hydrazine, a hydrazone, a carboxyl group or a salt thereof, a sulfonic acid group or a salt thereof, a phosphoric acid group or a salt thereof, a C1-C10 alkyl group, a C1-C10 alkoxy group, a C2-C10 alkenyl group, a C2-C10 alkynyl group, a C6-C16 aryl group, or a C6-C16 heteroaryl group. (Hereinafter, substituents of any substitution in the present application may be the same as those described above for alkyl groups.)

The unsubstituted C2-C60 alkenyl group indicates an unsaturated alkyl groups having at least one carbon-carbon double bond in the center or at a terminal of the alkyl group. Examples of the alkenyl group are an ethenyl group, a propenyl group, a butenyl group, and the like. At least one hydrogen atom in the unsubstituted alkenyl group may be substituted with a substituent described above in conjunction with the alkyl group.

The unsubstituted C2-C60 alkynyl group indicates an alkyl group having at least one carbon-carbon triple bond in the center or at a terminal of the alkyl group. Non-limiting examples of the unsubstituted C2-C20 alkynyl group are acetylene, propylene, phenylacetylene, naphthylacetylene, isopropylacetylene, t-butylacetylene, and diphenylacetylene. At least one hydrogen atom of the alkoxy group may be substituted with a substituent such as those described above in conjunction with the alkyl group.

The unsubstituted C3-C60 cycloalkyl group indicates a C3-C60 cyclic alkyl group wherein at least one hydrogen atom in the cycloalkyl group may be substituted with a substituent described above in conduction with the C1-C60 alkyl group.

The unsubstituted C1-C60 alkoxy group indicates a group having a structure of —OA wherein A is an unsubstituted C1-C60 alkyl group as described above. Non-limiting examples of the unsubstituted C1-C60 alkoxy group are a methoxy group, an ethoxy group, a propoxy group, an isopropyloxy group, a butoxy group, and a pentoxy group. At least one hydrogen atom of the alkoxy group may be substituted with a substituent such as those described above in conjunction with the alkyl group.

A C7-C60 aralkyl group indicates an aryl group linked to an alkyl group. Non-limiting examples of a substituted or unsubstituted aralkyl group are benzyl, 1-phenylethyl, 2-phenylethyl, 1-phenylisopropyl, 2-phenylisopropyl, phenyl-t-butyl, α-naphthylmethyl, 1-α-naphthylethyl, 2-α-naphthylethyl, 1-α-naphthylisopropyl, 2-α-naphthylisopropyl, β-naphthylmethyl, 1-β-naphthylethyl, 2-β-naphthylethyl, 1-β-naphthylisopropyl, 2-β-naphthylisopropyl, 1-pyrrolylmethyl, 2-(1-pyrrolyl)ethyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl groups.

A C1-C60 alkoxycarbonyl group may be represented by —COOZ, and examples of Z may be methyl, ethyl, propyl, isopropyl, n-butyl, s-butyl, isobutyl, t-butyl, n-pentyl, n-hexyl, n-heptyl, n-octyl, hydroxymethyl, 1-hydroxyethyl, 2-hydroxyethyl, 2-hydroxyisobutyl, 1,2-dihydroxyethyl, 1,3-dihydroxyisopropyl, 2,3-dihydroxy-t-butyl, 1,2,3-trihydroxypropyl, chloromethyl, 1-chloroethyl, 2-chloroethyl, 2-chloroisobutyl, 1,2-dichloroethyl, 1,3-dichloroisopropyl, 2,3-dichloro-t-butyl, 1,2,3-trichloropropyl, bromomethyl, 1-bromoethyl, 2-bromoethyl, 2-bromoisobutyl, 1,2-dibromoethyl, 1,3-dibromoisopropyl, 2,3-dibromo-t-butyl, 1,2,3-tribromopropyl, iodomethyl, 1-iodoethyl, 2-iodoethyl, 2-iodoisobutyl, 1,2-diiodoethyl, 1,3-diiodoisopropyl, 2,3-diiodo-t-butyl, 1,2,3-triiodopropyl, aminomethyl, 1-aminoethyl, 2-aminoethyl, 2-aminoisobutyl, 1,2-diaminoethyl, 1,3-diaminoisopropyl, 2,3-diamino-t-butyl, 1,2,3-triaminopropyl, cyanomethyl, 1-cyanoethyl, 2-cyanoethyl, 2-cyanoisobutyl, 1,2-dicyanoethyl, 1,3-dicyanoisopropyl, 2,3-dicyano-t-butyl, 1,2,3-tricyanopropyl, nitromethyl, 1-nitroethyl, 2-nitroethyl, 2-nitroisobutyl, 1,2-dinitroethyl, 1,3-dinitroisopropyl, 2,3-dinitro-t-butyl, and 1,2,3-trinitropropyl groups.

The unsubstituted C6-C60 aryl group indicates a carbocyclic aromatic system containing at least one ring. At least two rings may be fused to each other or linked to each other by a single bond. The term ‘aryl’ refers to an aromatic system, such as phenyl, naphthyl, or anthracenyl. At least one hydrogen atom in the aryl group may be substituted with a substituent described above in conjunction with the unsubstituted C1-C60 alkyl group.

Non-limiting examples of the a substituted or unsubstituted C6-C60 aryl group are a phenyl group, a C1-C10 alkylphenyl group (for example, ethylphenyl group), a halophenyl group (for example, a o-, m-, and p-fluorophenyl group or a dichlorophenyl group), a cyanophenyl group, a dicyanophenyl group, a trifluoromethoxyphenyl group, a biphenyl group, a halobiphenyl group, a cyanobiphenyl group, a C1-C10 alkyl biphenyl group, a C1-C10 alkoxybiphenyl group, a o-, m-, and p-toryl group, an o-, m-, and p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C1-C10 alkylnaphthyl group (for example, methylnaphthyl group), a C1-C10 alkoxynaphthyl group (for example, methoxynaphthyl group), a cyanonaphthyl group, an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylene group, a pyrenyl group, a chrycenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronelyl group, a trinaphthylenyl group, a heptaphenyl group, a heptacenyl group, a pyranthrenyl group, and an ovalenyl group.

The unsubstituted C3-C60 heteroaryl group used herein includes one, two or three hetero atoms selected from N, O, P and S. At least two rings may be fused to each other or linked to each other by a single bond. Non-limiting examples of the unsubstituted C4-C60 heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazol group, an indol group, a quinolyl group, an isoquinolyl group, and a dibenzothiophene group. In addition, at least one hydrogen atom in the heteroaryl group may be substituted with a substituent described above in conjunction with the unsubstituted C1-C60 alkyl group.

The unsubstituted C6-C60 aryloxy group is a group represented by —OA₁ wherein A₁ may be a C6-C60 aryl group. An example of the aryloxy group is a phenoxy group. At least one hydrogen atom in the aryloxy group may be substituted with a substituent described above in conjunction with the unsubstituted C1-C60 alkyl group.

The unsubstituted C6-C60 arylthio group is a group represented by —SA₁ wherein A₁ may be a C6-C60 aryl group. Non-limiting examples of the arylthio group are a benzenethio group and a naphthylthio group. At least one hydrogen atom in the arylthio group may be substituted with a substituent described above in conjunction with the unsubstituted C1-C60 alkyl group.

The unsubstituted C6-C60 condensed polycyclic group used herein refers to a substituent including at least two rings wherein at least one aromatic ring and at least one non-aromatic ring are fused to each other, or refers to a substituent having an unsaturated group in a ring that may not form a conjugate structure. The unsubstituted C6-C60 condensed polycyclic group is distinct from an aryl group or a heteroaryl group in terms of being non-aromatic.

A condensed polycyclic group including N, O, or S refers to a substituent including N, O, or S, and at least two rings wherein at least one aromatic ring and at least one non-aromatic ring are fused to each other, or refers to a substituent having an unsaturated group in a ring that may not form a conjugate structure. The condensed polycyclic group is non-aromatic in general.

A hydrogen atom of at least one of the condensed polycyclic group or the condensed polycyclic group including N, O, or S may be substituted with the same substituents of the C1-C60 alkyl group as described above.

Non-limiting examples of the compound represented by Formula 1 are compounds represented by the following formulae:

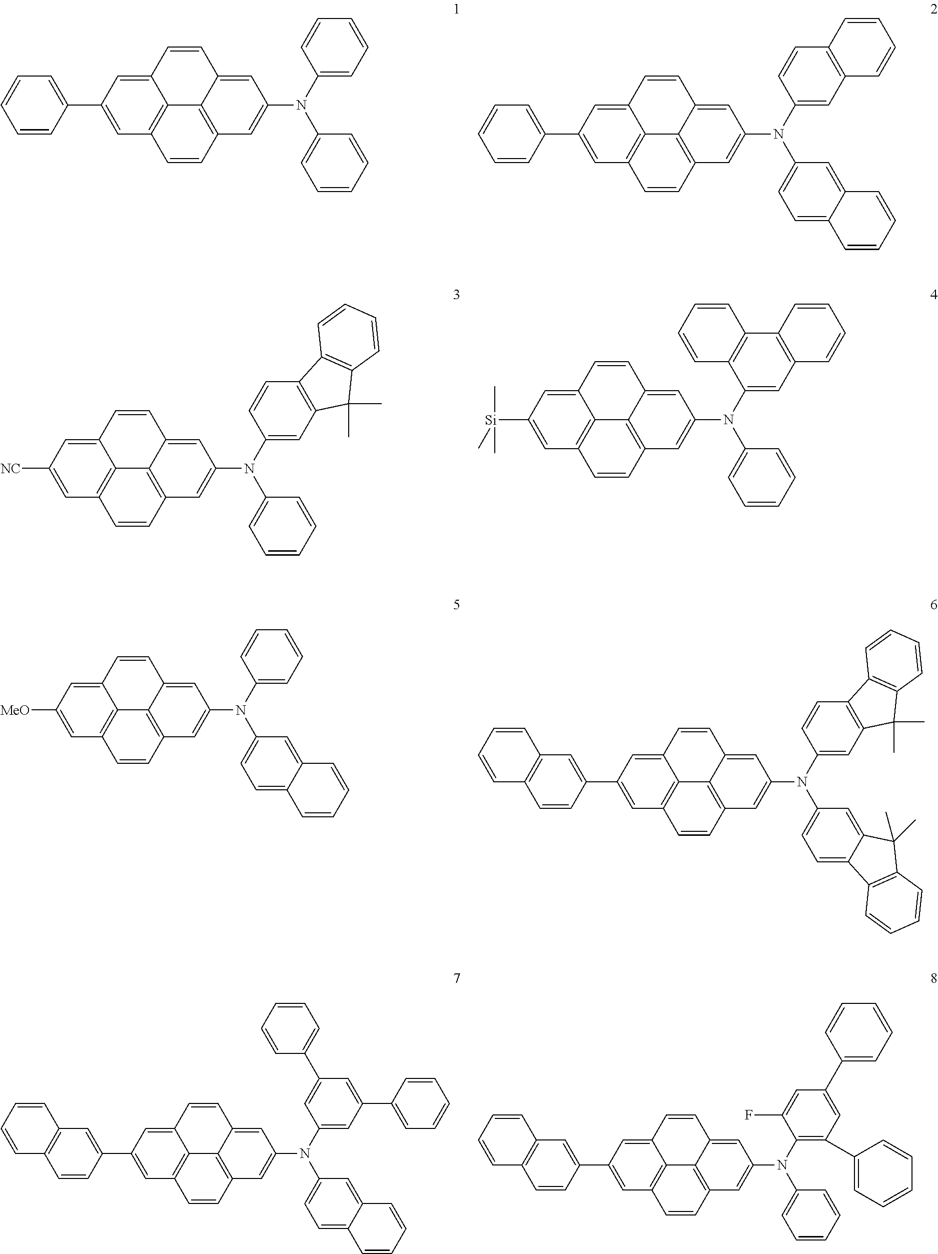

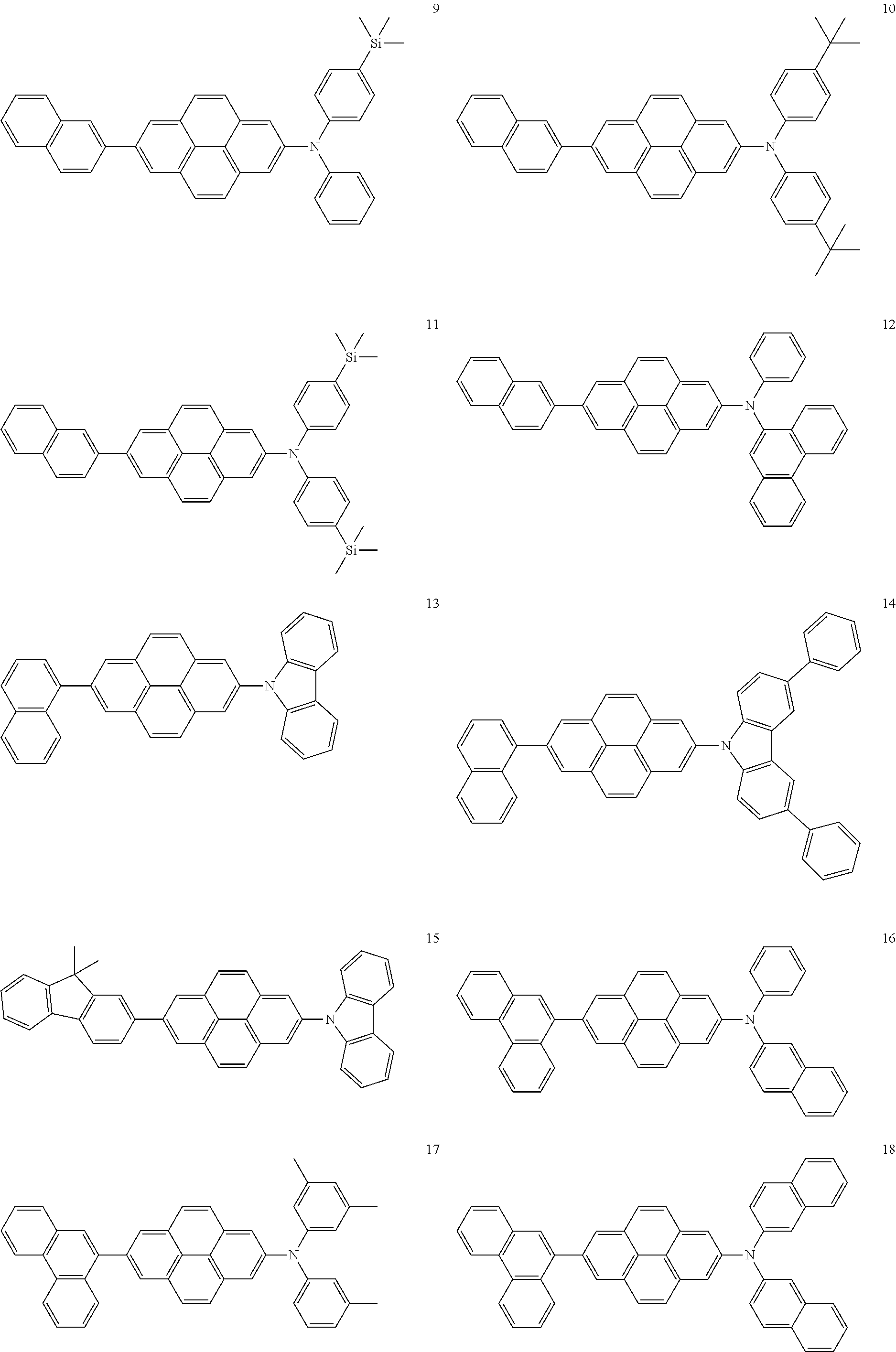

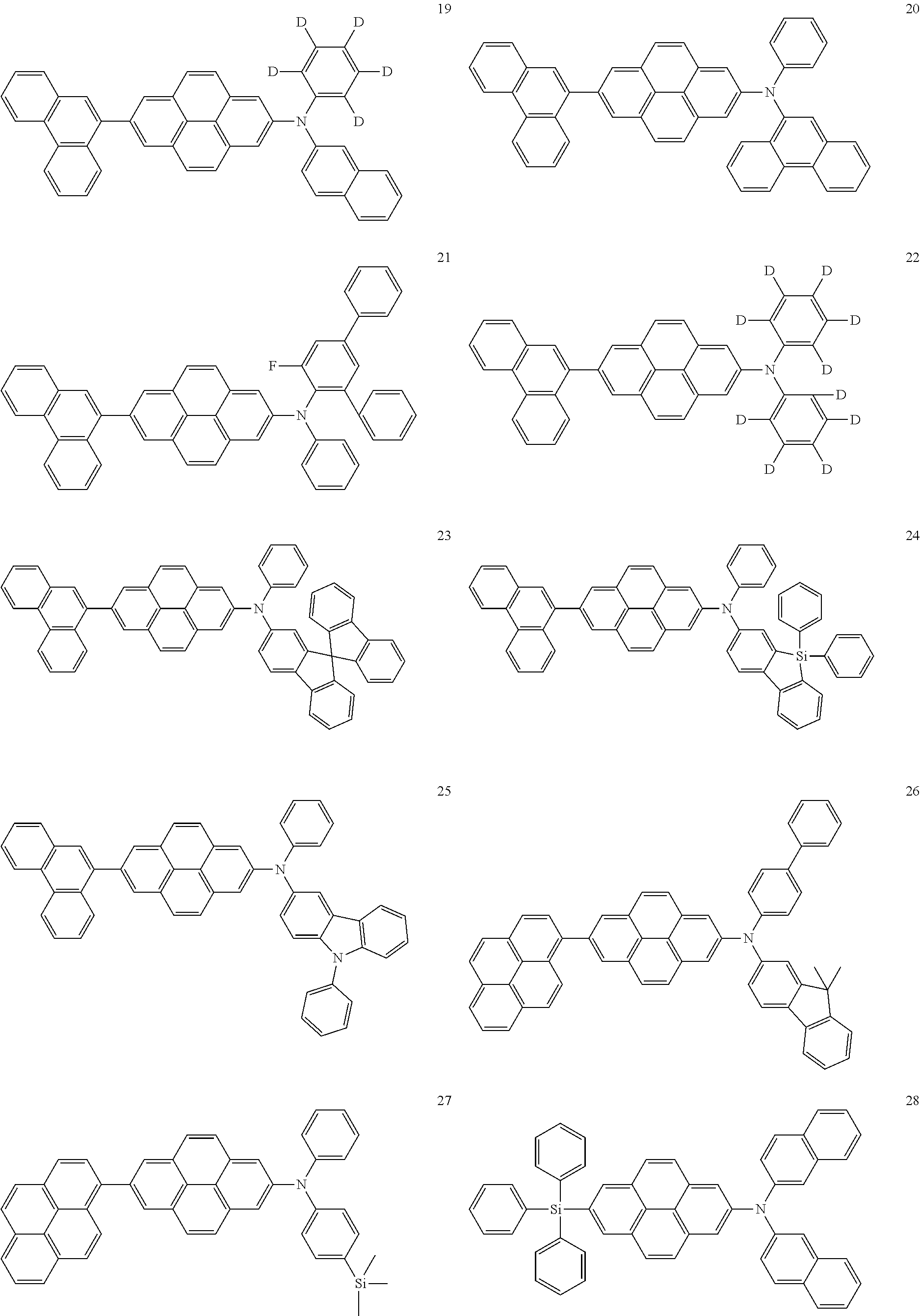

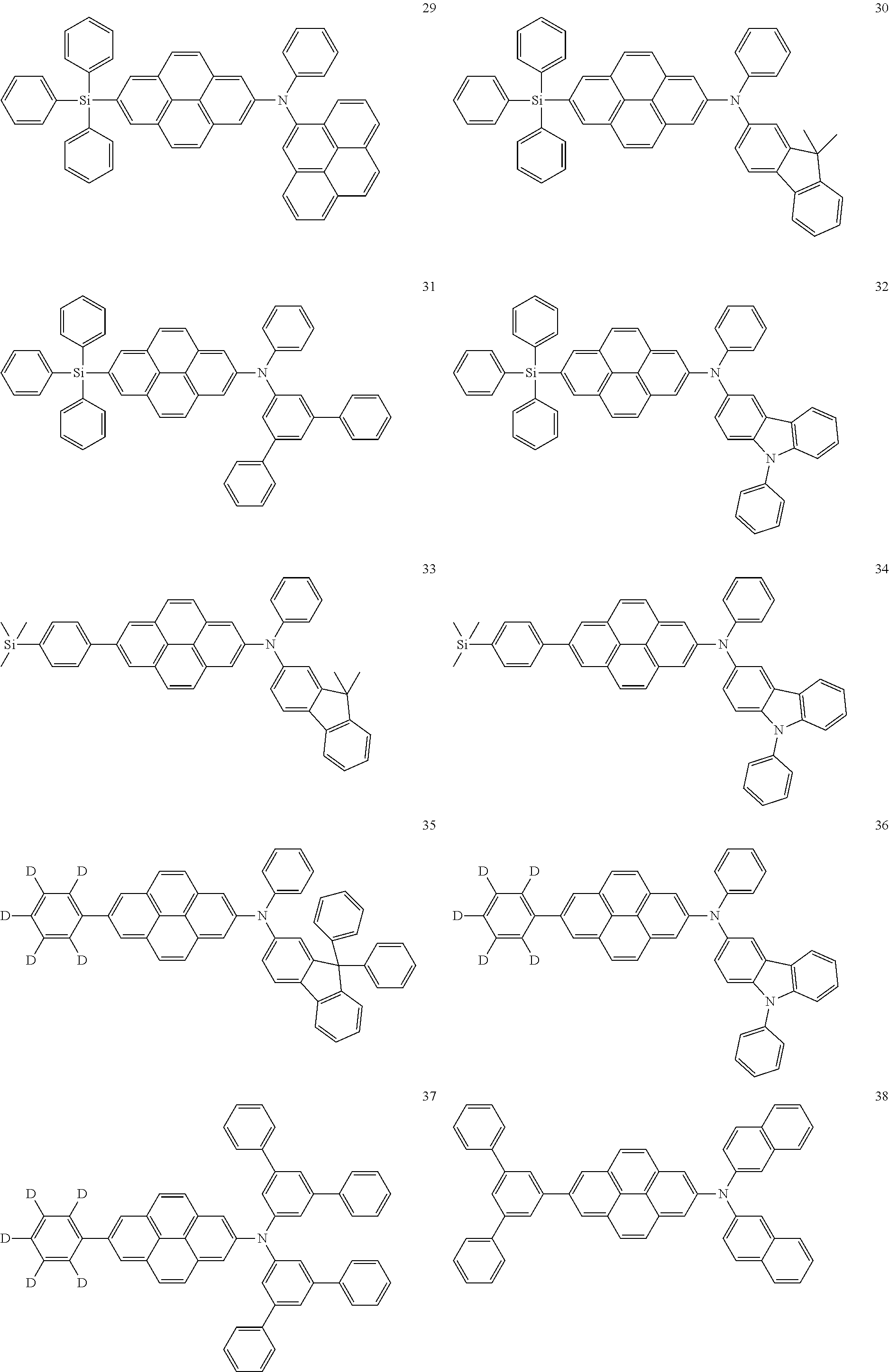

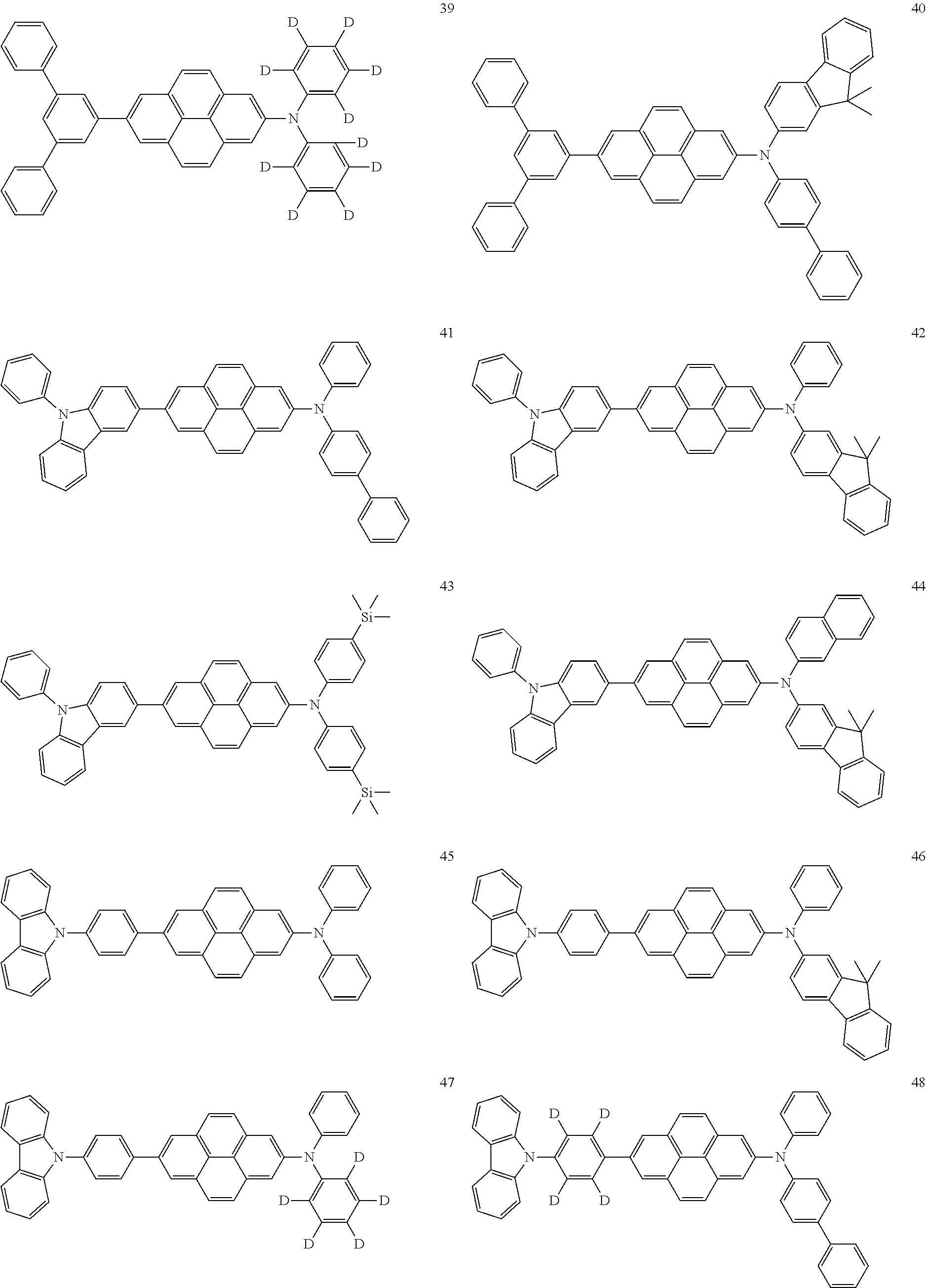

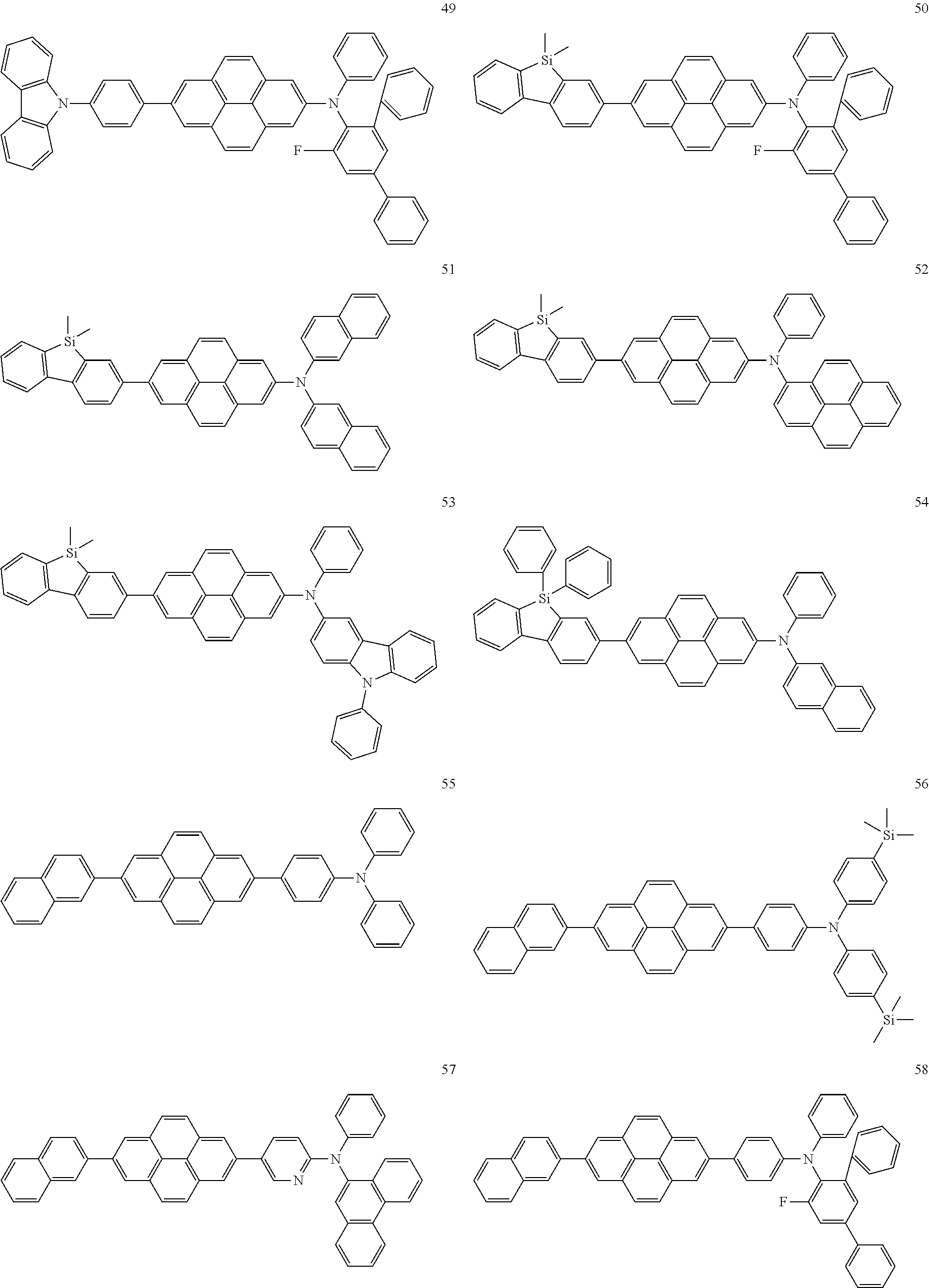

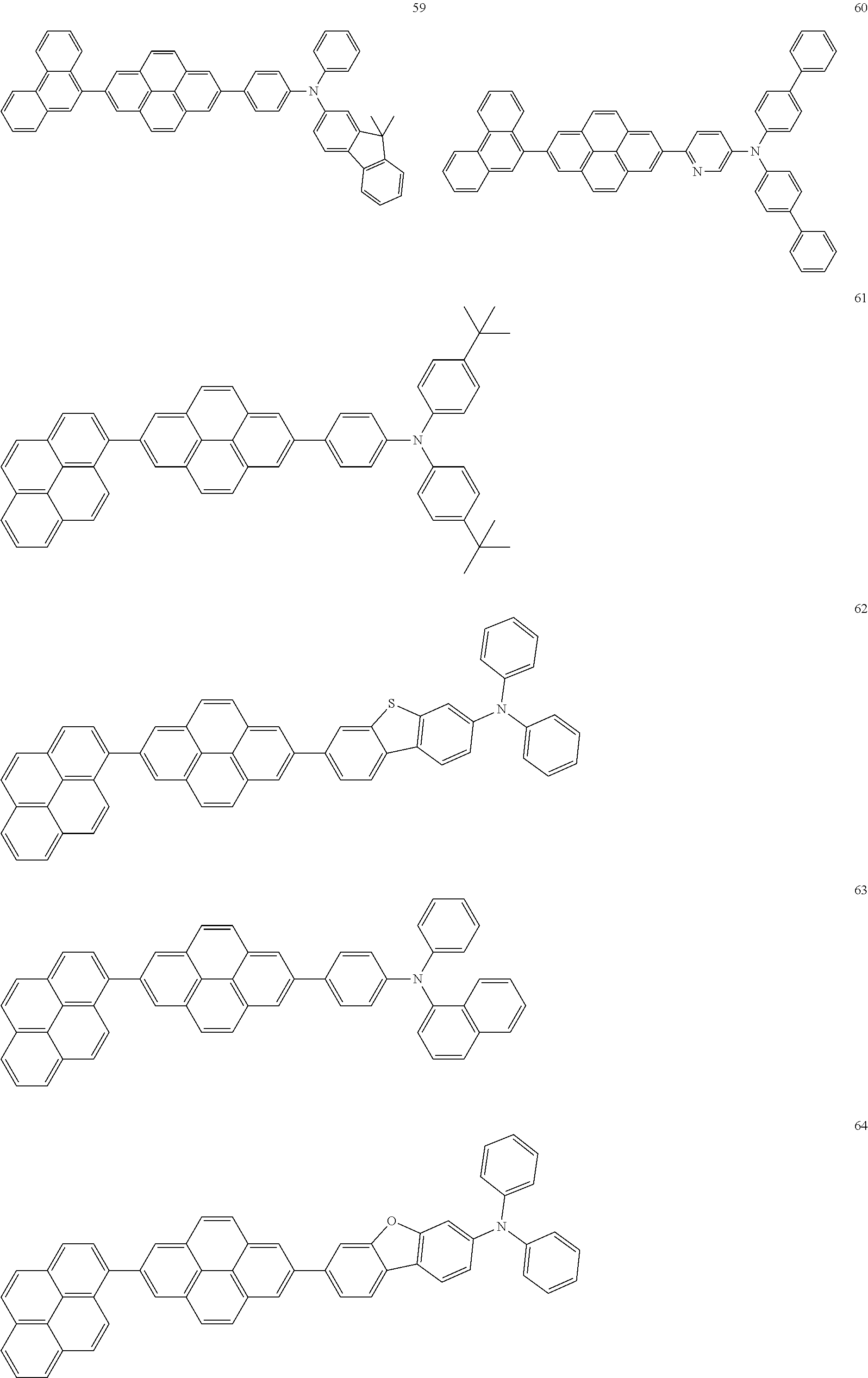

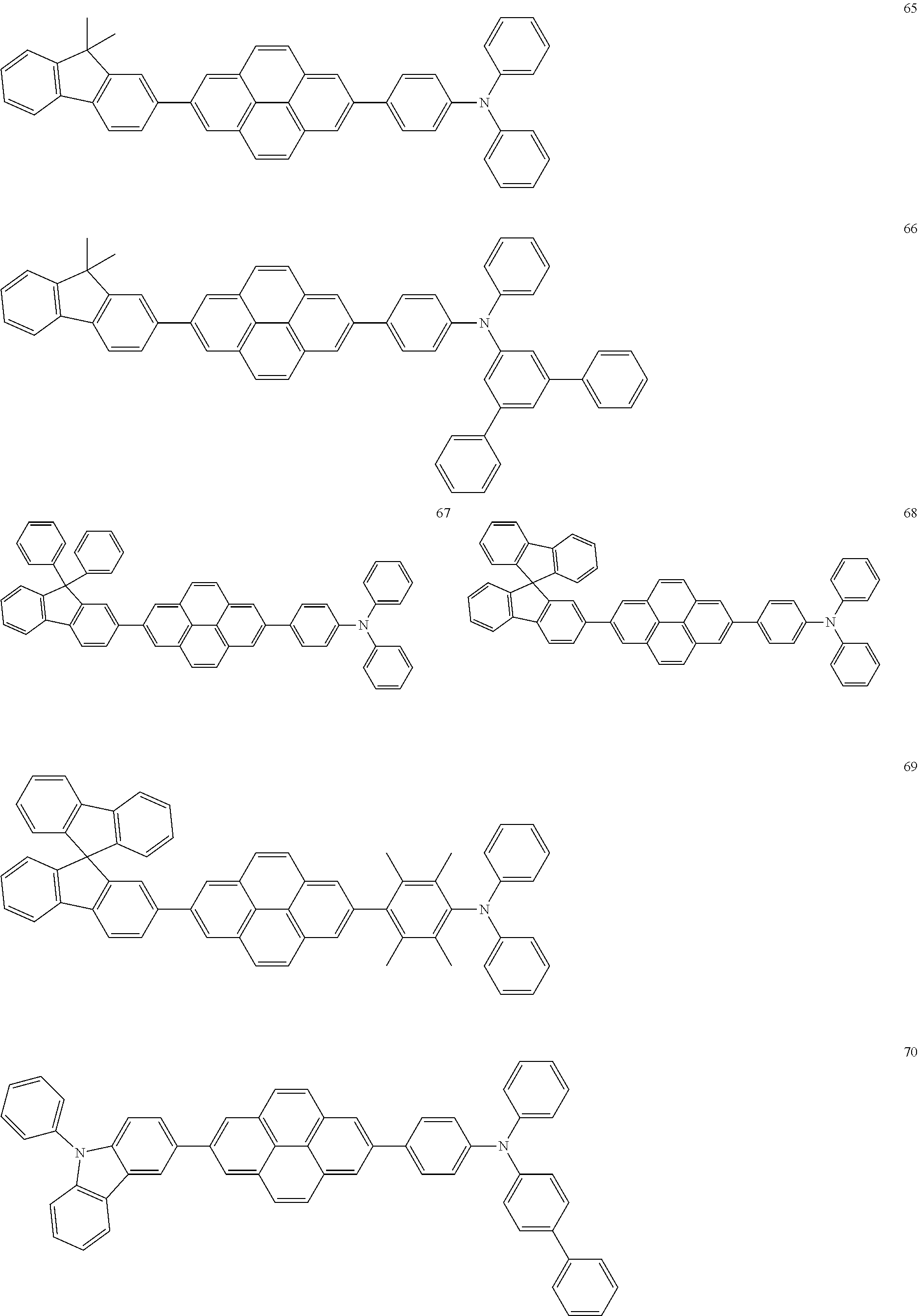

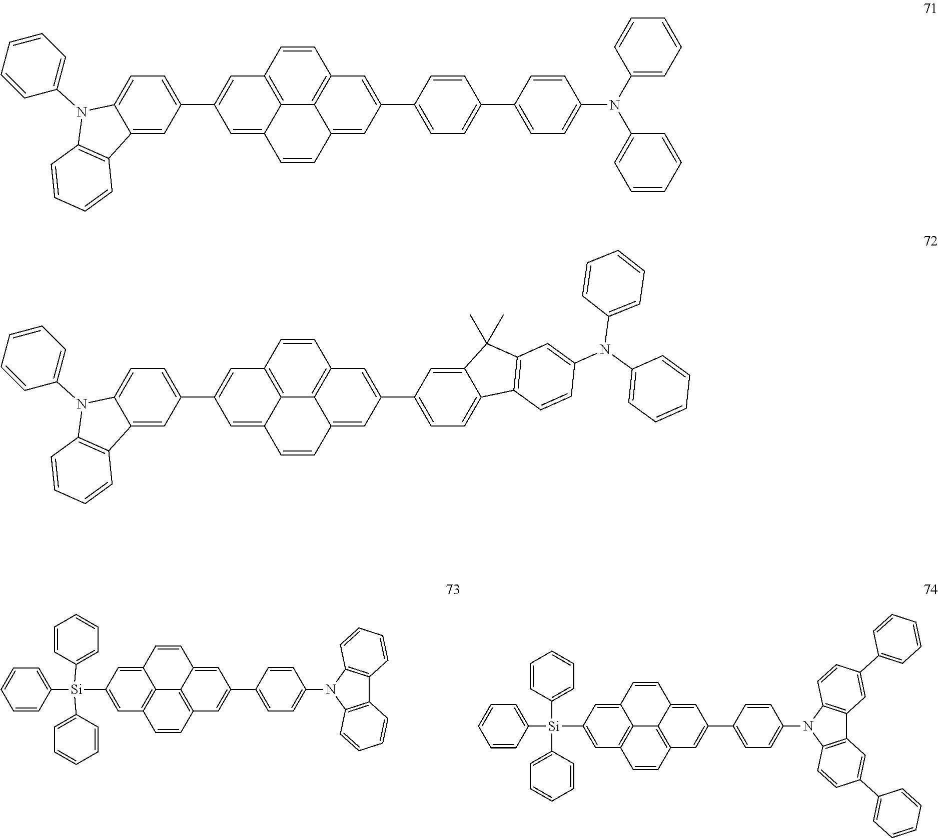 [SMILES: c1ccc(N(c2ccccc2)c2ccc(-c3ccc(-c4cc5ccc6cc(-c7ccc8c(c7)c7ccccc7n8-c7ccccc7)cc7ccc(c4)c5c67)cc3)cc2)cc1 ; CC1(C)c2cc(-c3cc4ccc5cc(-c6ccc7c(c6)c6ccccc6n7-c6ccccc6)cc6ccc(c3)c4c56)ccc2-c2ccc(N(c3ccccc3)c3ccccc3)cc21 ; c1ccc([Si](c2ccccc2)(c2ccccc2)c2cc3ccc4cc(-c5ccc(-n6c7ccccc7c7ccccc76)cc5)cc5ccc(c2)c3c45)cc1 ; c1ccc(-c2ccc3c(c2)c2cc(-c4ccccc4)ccc2n3-c2ccc(-c3cc4ccc5cc([Si](c6ccccc6)(c6ccccc6)c6ccccc6)cc6ccc(c3)c4c56)cc2)cc1]

Another aspect of the present invention provides an organic light-emitting device including the organic layer. The organic layer may include at least one layer selected from among a hole injection layer, a hole transport layer, a functional layer having both hole injection and hole transport capabilities (hereinafter, “H-functional layer”), a buffer layer, an electron blocking layer, an emission layer, a hole blocking layer, an electron transport layer, an electron injection layer, and a functional layer having both electron injection and electron transport capabilities (hereinafter, “E-functional layer”).

In particular, the organic layer may be used as an emission layer or a hole transport layer. Particularly, for example, the organic layer may be a blue emission layer.

In some embodiments, the organic light-emitting device may include an electron injection layer, an electron transport layer, an emission layer, a hole injection layer, a hole transport layer, or a functional layer having both hole injection and transport capabilities; the electron injection layer, the electron transport layer, or the functional layer having both electron injection and transport capabilities may include the compound of Formula 1 above; and the emission layer may include the compound of Formula 1 and an anthracene-based compound, an arylamine-based compound or a styryl-based compound.

In some other embodiments, the organic light-emitting device may include an electron injection layer, an electron transport layer, an emission layer, a hole injection layer, a hole transport layer, or a functional layer having both hole injection and transport capabilities; at least one of a red emission layer, a green emission layer, a blue emission layer, and a white emission layer of the emission layer may include a phosphorescent compound; and at least one of the hole injection layer, the hole transport layer, and the functional layer having both hole injection and hole transport capabilities may include a charge-generating material. In some embodiments, the charge-generating material may be a p-dopant, and the p-dopant may be a quinine derivative, a metal oxide, or a cyano group-containing compound.

In some embodiments, the organic layer may include an electron transport layer, and the electron transport layer may include an electron-transporting organic compound and a metal complex. The metal complex may be a lithium (Li) complex.

The term “organic layer” as used herein refers to a single layer and/or a plurality of layers disposed between the first and second electrodes of the organic light-emitting device.

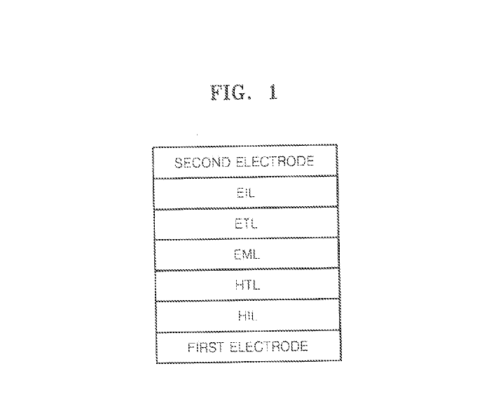

FIG. 1 is a schematic sectional view of an organic light-emitting device according to an embodiment of the present invention. Hereinafter, a structure of an organic light-emitting device according to an embodiment of the present invention and a method of manufacturing the same will now be described with reference to FIG. 1.

A substrate (not shown) may be any substrate that is used in existing organic light emitting devices. In some embodiments the substrate may be a glass substrate or a transparent plastic substrate with strong mechanical strength, thermal stability, transparency, surface smoothness, ease of handling, and water resistance.

The first electrode may be formed by depositing or sputtering a first electrode-forming material on the substrate. When the first electrode is an anode, a material having a high work function may be used as the first electrode-forming material to facilitate hole injection. The first electrode may be a reflective electrode or a transmission electrode. Transparent and conductive materials such as ITO, IZO, SnO₂, and ZnO may be used to form the first electrode. The first electrode may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode may have a single-layer structure or a multi-layer structure including at least two layers. For example, the first electrode may have a three-layered structure of ITO/Ag/ITO, but is not limited thereto.

An organic layer may be disposed on the first electrode.

The organic layer may include a hole injection layer (HIL), a hole transport layer (HTL), a buffer layer (not shown), an emission layer (EML), an electron transport layer (ETL), or an electron injection layer (EIL).

The HIL may be formed on the first electrode by vacuum deposition, spin coating, casting, Langmuir-Blodgett (LB) deposition, or the like.

When the HIL is formed using vacuum deposition, vacuum deposition conditions may vary according to the compound that is used to form the HIL, and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed using spin coating, the coating conditions may vary according to the material that is used to form the HIL, and the desired structure and thermal properties of the HIL to be formed. For example, the coating rate may be in the range of about 2000 rpm to about 5000 rpm, and a temperature at which heat treatment is performed to remove a solvent after coating may be in the range of about 80° C. to about 200° C. However, the coating conditions are not limited thereto.

The HIL may be formed of any material that is commonly used to form a HIL. Non-limiting examples of the material that can be used to form the HIL are N,N′-diphenyl-N,N′-bis-[4-(phenyl-m-tolyl-amino)-phenyl]-biphenyl-4,4′-diamine, (DNTPD), a phthalocyanine compound such as copperphthalocyanine, 4,4′,4″-tris (3-methylphenylphenylamino) triphenylamine (m-MTDATA), N,N′-di(1-naphthyl)-N,N′-diphenylbenzidine (NPB), TDATA, 2T-NATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), and polyaniline)/poly(4-styrenesulfonate (PANI/PSS).

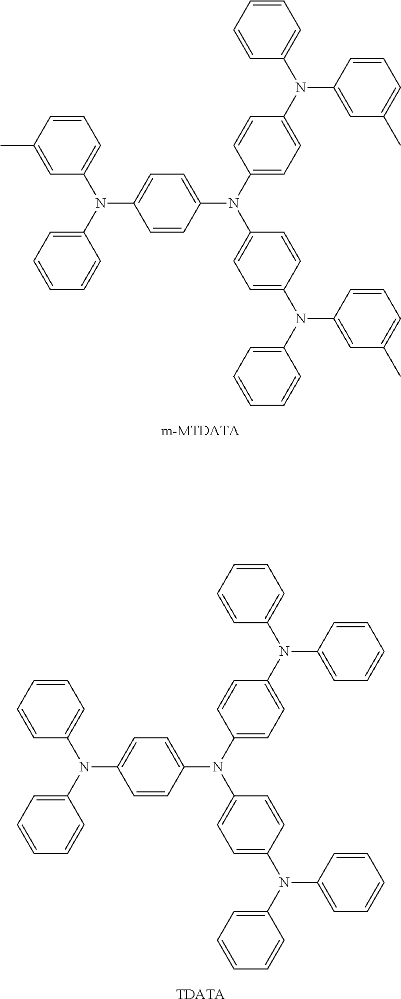

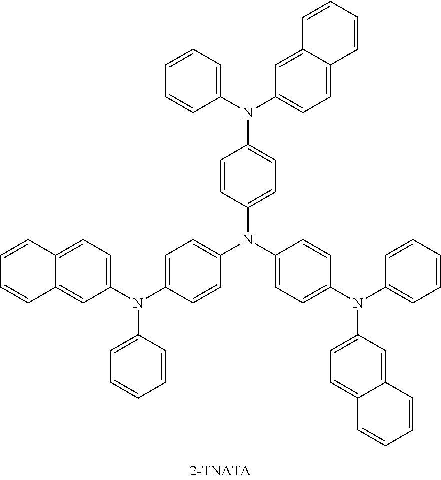 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

The thickness of the HIL may be from about 100 Å to about 10000 Å, and in some embodiments, may be from about 100 Å to about 1000 Å. When the thickness of the HIL is within these ranges, the HIL may have good hole injecting ability without a substantial increase in driving voltage.

Then, a HTL may be formed on the HIL by using vacuum deposition, spin coating, casting, Langmuir-Blodgett (LB) deposition, or the like. When the HTL is formed using vacuum deposition or spin coating, the conditions for deposition and coating may be similar to those for the formation of the HIL, though the conditions for the deposition and coating may vary according to the material that is used to form the HTL.

The HTL may be formed of the compound of Formula 1 or any known hole transporting materials. Non-limiting examples of suitable known HTL forming materials are carbazole derivatives, such as N-phenylcarbazole or polyvinylcarbazole, N,N′-bis(3-methylphenyl)-N,N-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB).

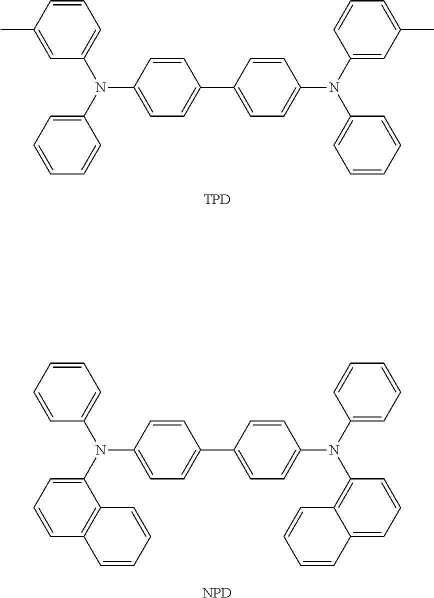

The thickness of the HTL may be from about 50 Å to about 2000 Å, and in some embodiments, from about 100 Å to about 1500 Å. When the thickness of the HTL is within these ranges, the HTL may have good hole transporting ability without a substantial increase in driving voltage.

The H-functional layer (having both hole injection and hole transport capabilities) may contain at least one material from each group of the hole injection layer materials and hole transport layer materials. The thickness of the H-functional layer may be from about 500 Å to about 10,000 Å, and in some embodiments, may be from about 100 Å to about 1,000 Å. When the thickness of the H-functional layer is within these ranges, the H-functional layer may have good hole injection and transport capabilities without a substantial increase in driving voltage.

In some embodiments, at least one of the HIL, HTL, and H-functional layer may include at least one of a compound of Formula 300 below and a compound of Formula 350 below:

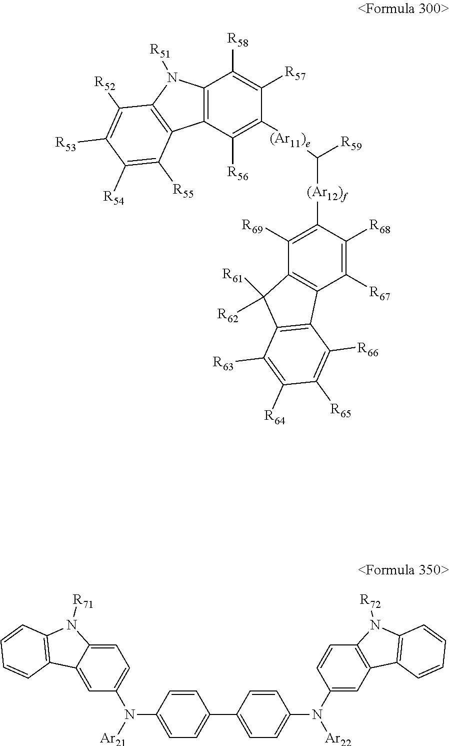

In Formulae 300 and 350, Ar₁₁, Ar₁₂, Ar₂₁, and Ar₂₂ may be each independently a substituted or unsubstituted C₅-C₆₀ arylene group.

In Formula 300, e and f may be each independently an integer from 0 to 5, for example, may be 0, 1, or 2. In a non-limiting embodiment, e may be 1, and f may be 0.

In Formulae 300 and 350 above, R₅₁ to R₅₈, R₆₁ to R₆₉, and R₇₁ to R₇₂ may be each independently a hydrogen atom, a deuterium atom, a halogen atom, a hydroxyl group, a cyano group, a nitro group, an amino group, an amidino group, a hydrazine group, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group. In some embodiments, R₅₁ to R₅₈, R₆₁ to R₆₉, R₇₁, and R₇₂ may be each independently one of a hydrogen atom; a deuterium atom; a halogen atom; a hydroxyl group; a cyano group; a nitro group; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, or the like); a C₁-C₁₀ alkoxy group (for example, a methoxy group, an ethoxy group, a propoxy group, a butoxy group, a pentoxy group, or the like); a C₁-C₁₀ alkyl group and a C₁-C₁₀ alkoxy group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C1-C10 alkoxy group.

In Formula 300, R₅₉ may be one of a phenyl group, a naphthyl group, an anthryl group, a biphenyl group, a pyridyl group; and a phenyl group, a naphthyl group, an anthryl group, a biphenyl group, and a pyridyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In an embodiment the compound of Formula 300 may be a compound represented by Formula 300A below:

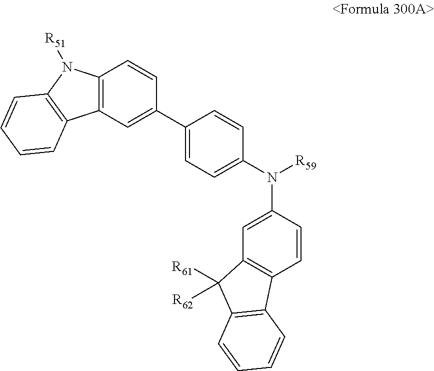

In Formula 300A, R₅₁, R₆₀, R₆₁, and R₅₉ may be as defined above.

In some non-limiting embodiments, at least one of the HIL, HTL, and H-functional layer may include at least one of compounds represented by Formulae 301 to 320 below:

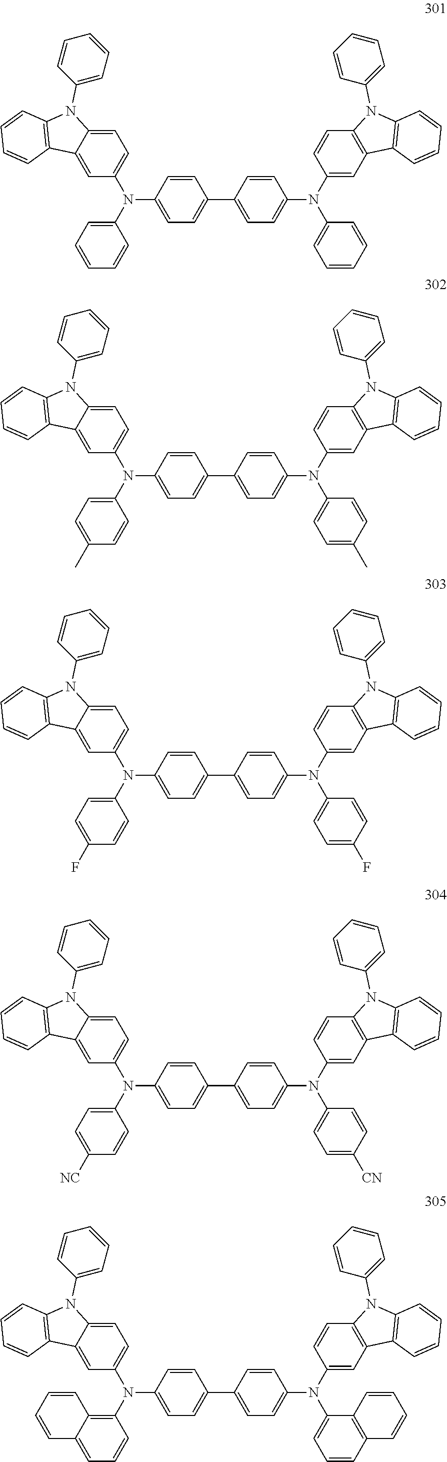

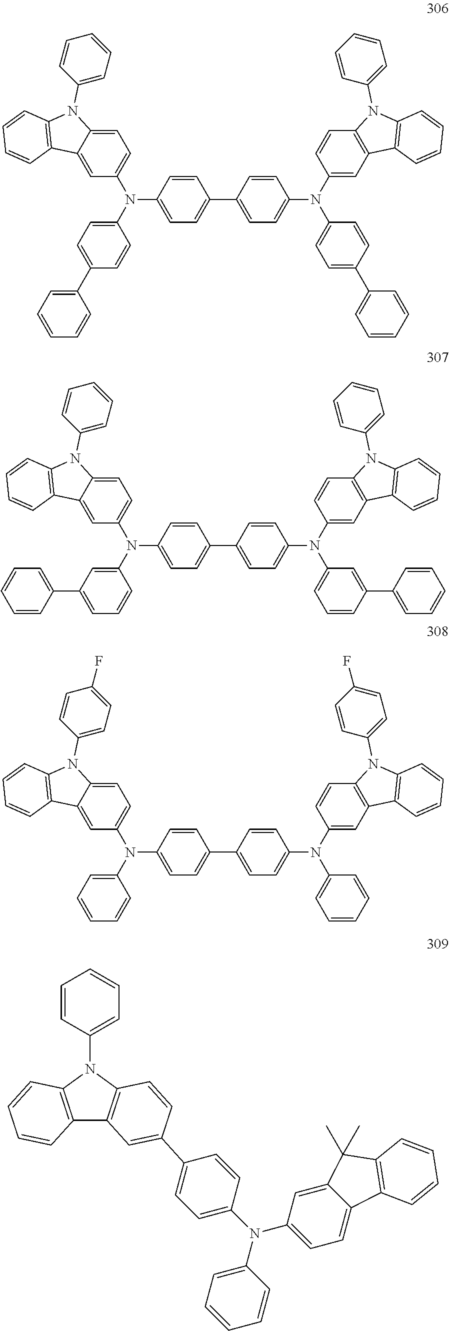 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

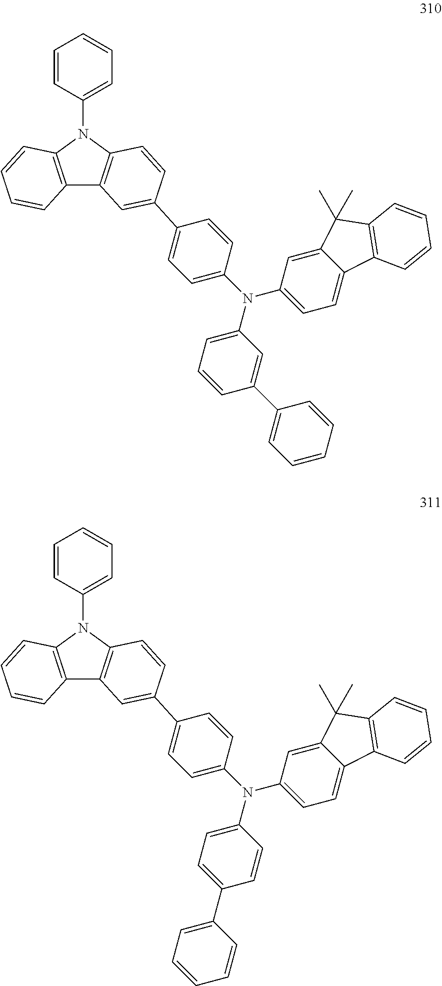 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

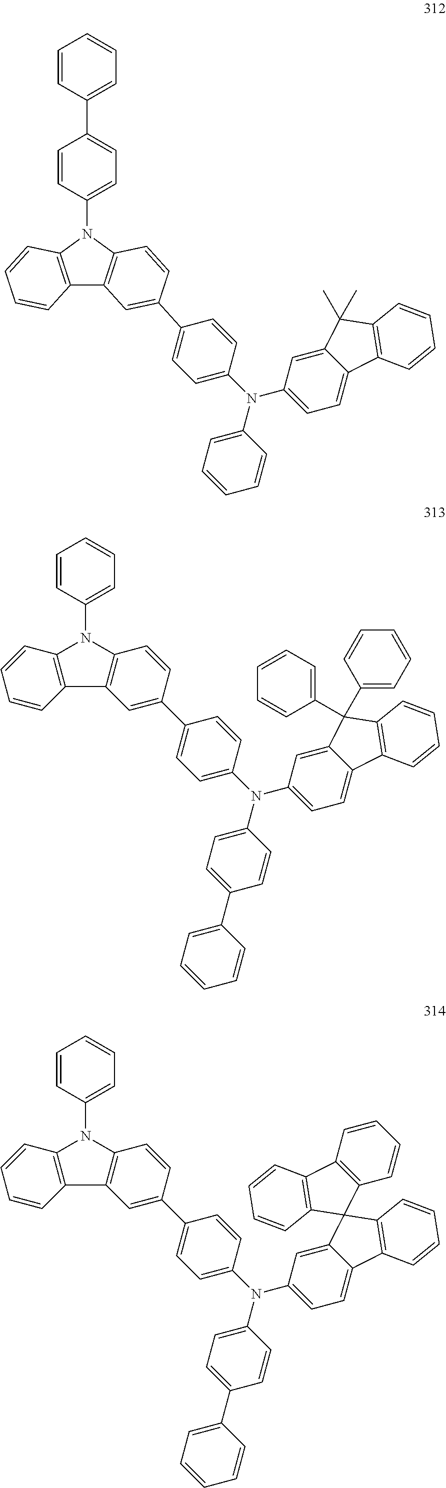 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

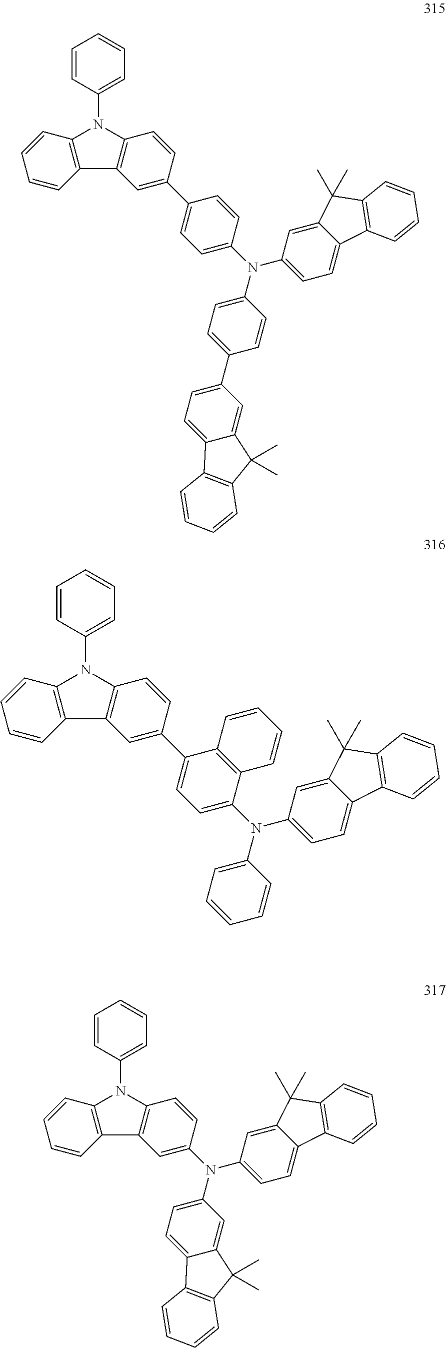 [SMILES: CC1(C)c2ccccc2-c2ccc(-c3ccc(N(c4ccc(-c5ccc6c(c5)c5ccccc5n6-c5ccccc5)cc4)c4ccc5c(c4)C(C)(C)c4ccccc4-5)cc3)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

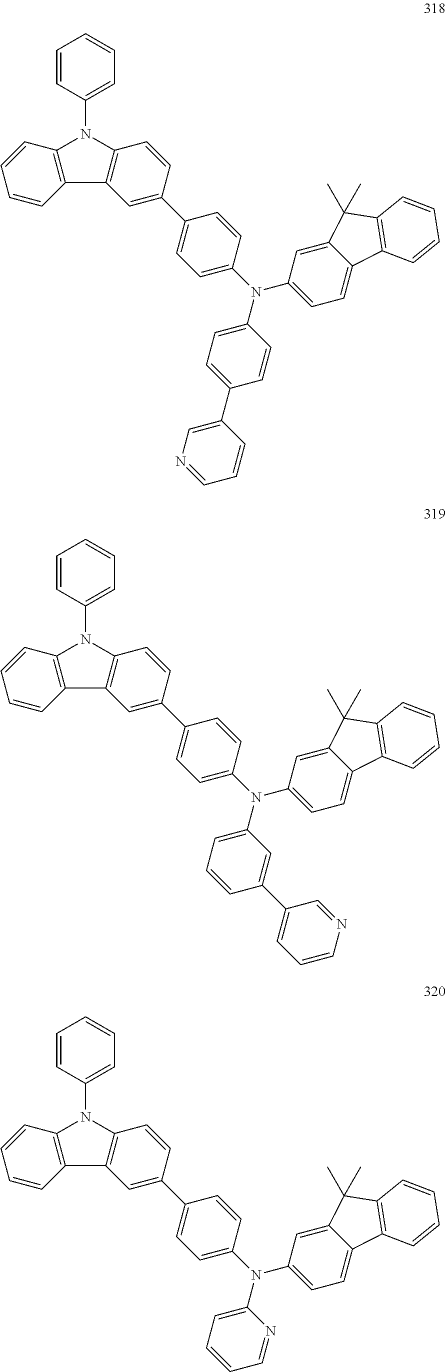 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, HTL, and H-functional layer may further include a charge-generating material for improved layer conductivity, in addition to a known hole injecting material, hole transport material, and/or material having both hole injection and hole transport capabilities as described above.

The charge-generating material may be, for example, a p-dopant. The p-dopant may be one of quinine derivatives, metal oxides, and compounds with a cyano group, but are not limited thereto. Non-limiting examples of the p-dopant are quinone derivatives such as tetracyanoquinonedimethane (TCNQ), 2,3,5,6-tetrafluoro-tetracyano-1,4-benzoquinonedimethane (F4-CTNQ), and the like; metal oxides such as tungsten oxide, molybdenum oxide, and the like; and cyano-containing compounds such as Compound 200 below:

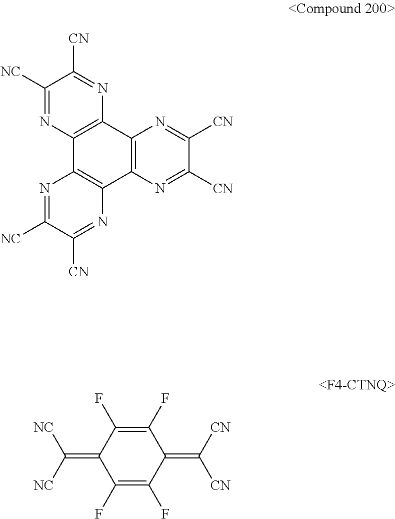 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, hole transport layer, or H-functional layer further includes a charge-generating material, the charge-generating material may be homogeneously dispersed or inhomogeneously distributed in the layer.

A buffer layer may be disposed between at least one of the HIL, HTL, and H-functional layer, and the EML. The buffer layer may compensate for an optical resonance distance of light according to a wavelength of the light emitted from the EML, and thus may increase efficiency. The butter layer may include any hole injecting material or hole transporting material that are widely known. In some other embodiments, the buffer layer may include the same material as one of the materials included in the HIL, HTL, and H-functional layer that underly the buffer layer.

Then, an EML may be formed on the HTL, H-functional layer, or buffer layer by vacuum deposition, spin coating, casting, LB deposition, or the like. When the EML is formed using vacuum deposition or spin coating, the deposition and coating conditions may be similar to those for the formation of the HIL, though the conditions for deposition and coating may vary according to the material that is used to form the EML.

The host may be formed of the compound of Formula 1 or any known host materials. Non-limiting examples of the host are Alq3, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di-2-naphthylanthracene (TBADN), E3, distyrylarylene (DSA), dmCBP (see a formula below), and Compounds 501 to 509 below:

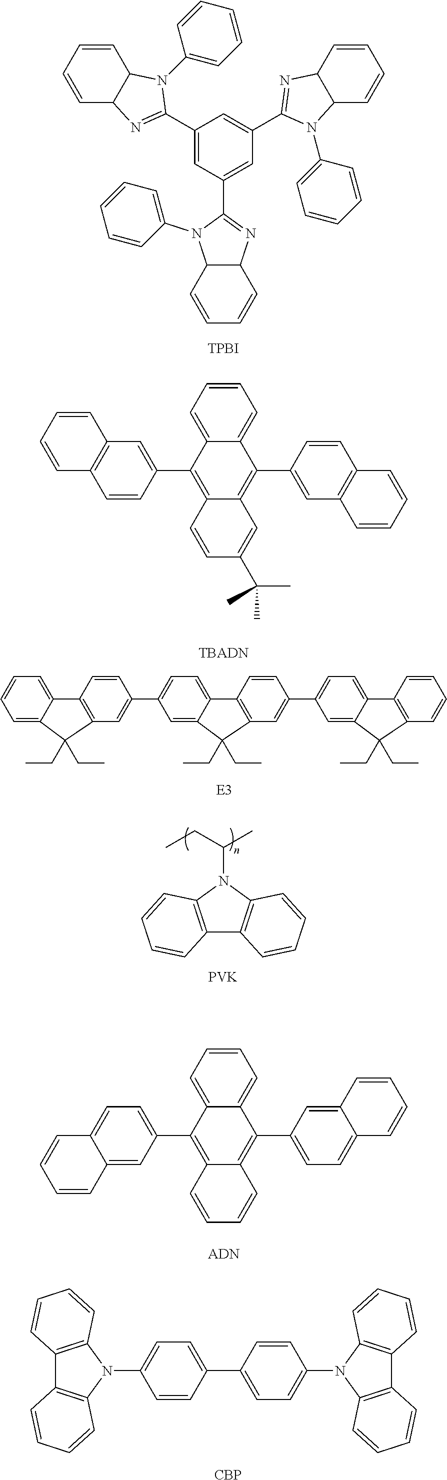

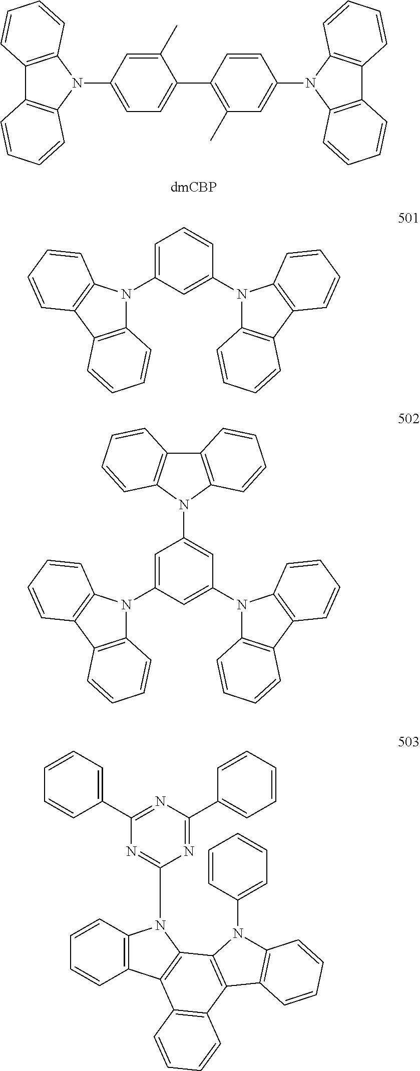

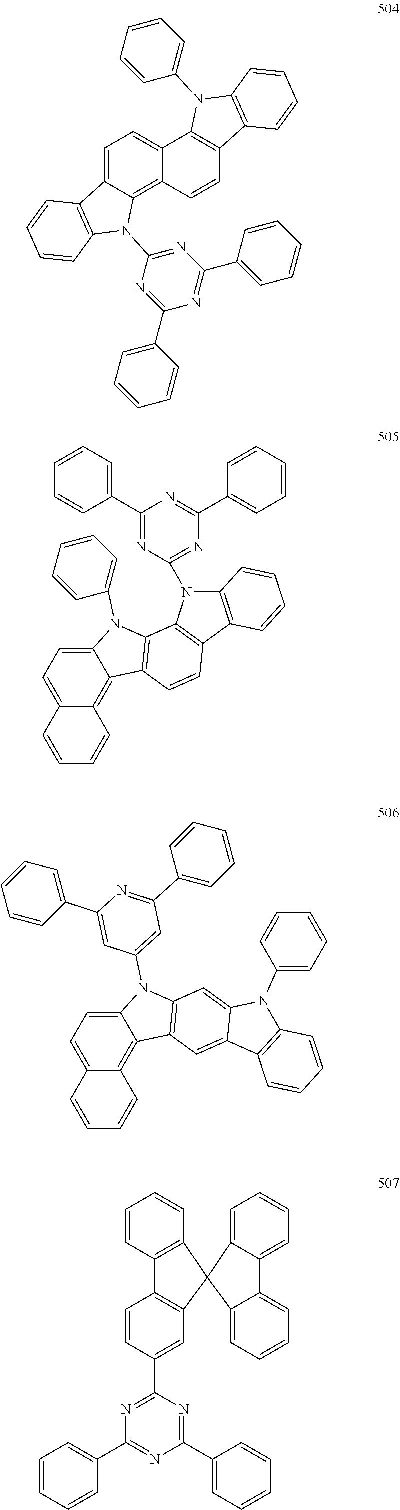 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1 ; c1ccc(-c2nc(-c3ccccc3)nc(-c3ccc4c(c3)C3(c5ccccc5-c5ccccc53)c3ccccc3-4)n2)cc1]

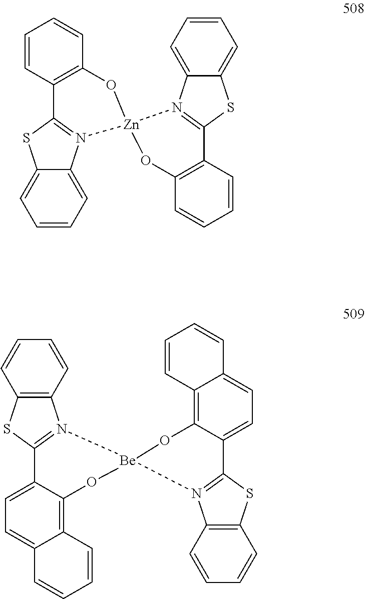

In some embodiments, an anthracene-based compound represented by Formula 400 below may be used as the host.

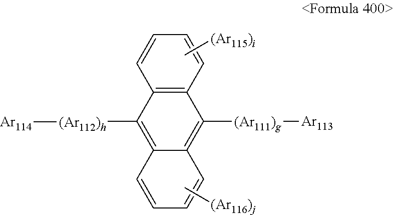

In Formula 400, Ar₁₁₁ and Ar₁₁₂ may be each independently a substituted or unsubstituted C₅-C₆₀arylene group; Ar₁₁₃ to Ar₁₁₆ may be each independently a substituted or unsubstituted C₁-C₁₀alkyl group, or a substituted or unsubstituted C₅-C₆₀aryl group; and g, h, i, and j may be each independently an integer from 0 to 4.

In some non-limiting embodiments, Ar₁₁₁ and Ar₁₁₂ in Formula 400 may be each independently a phenylene group, a naphthylene group, a phenanthrenylene group, or a pyrenylene group; or a phenylene group, a naphthylene group, a phenanthrenylene group, a fluorenyl group, or a pyrenylene group that are substituted with at least one of a phenyl group, a naphthyl group, and an anthryl group.

In Formula 400 above, g, h, I, and j may be each independently 0, 1, or 2.

In Formula 400, Ar₁₁₃ to Ar₁₁₆ may be each independently one of a C₁-C₁₀alkyl group that is substituted with at least one of a phenyl group, a naphthyl group, and an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, and a fluorenyl group that are substituted with at least one of a deuterium atom, a halogen atom, a hydroxyl group, a cyano group, a nitro group, an amino group, an amidino group, a hydroxyrazine, a hydroxyrazone, a carboxyl group or a salt thereof, a sulfonic acid group or a salt thereof, a phosphoric acid group or a salt thereof, a C₁-C₆₀alkyl group, a C₂-C₆₀alkenyl group, a C₂-C₆₀alkynyl group, a C₁-C₆₀alkoxy group, a phenyl group, a naphthyl group, an anthryl group, a pyrenyl group, a phenanthrenyl group, and a fluorenyl group; and

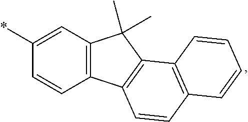 [SMILES: *c1ccc2c(c1)C(C)(C)c1c-2ccc2ccccc12]

but are not limited thereto.

For example, the anthracene-based compound of Formula 400 above may be one of the compounds represented by the following formulae, but is not limited thereto:

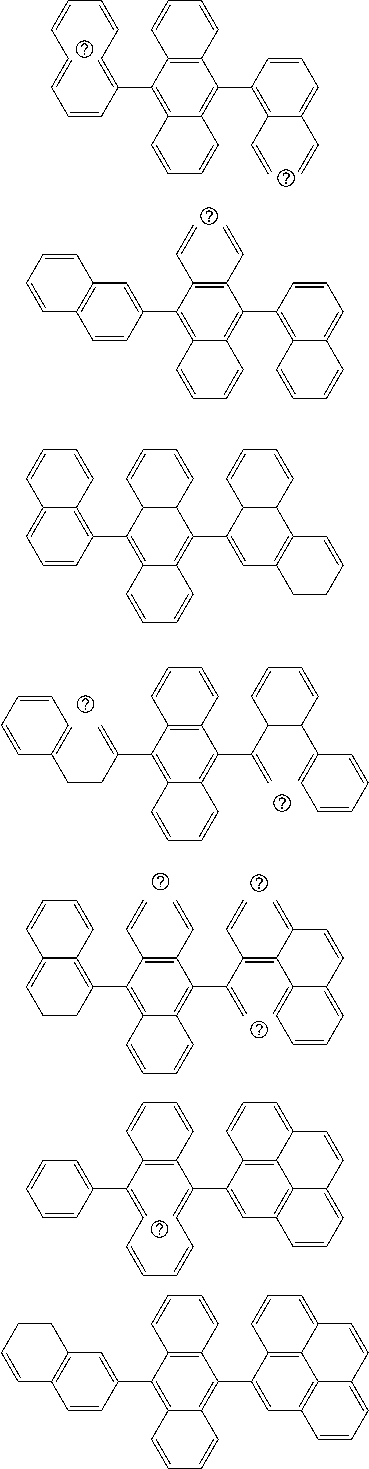

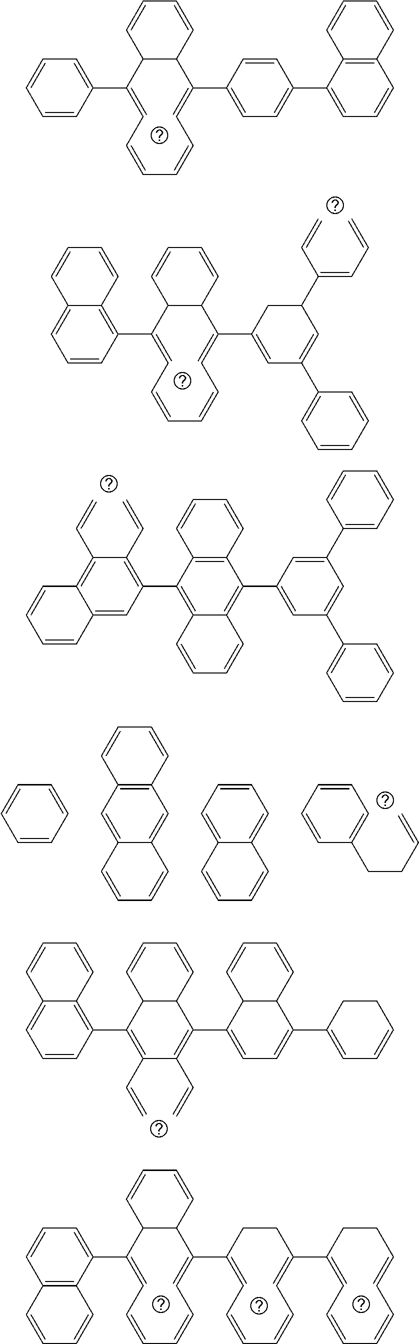

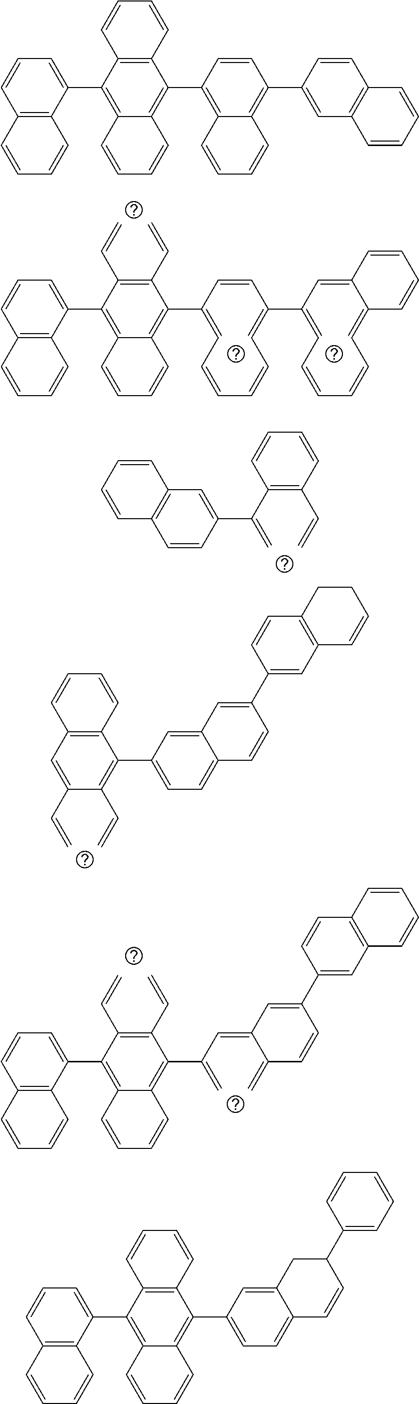

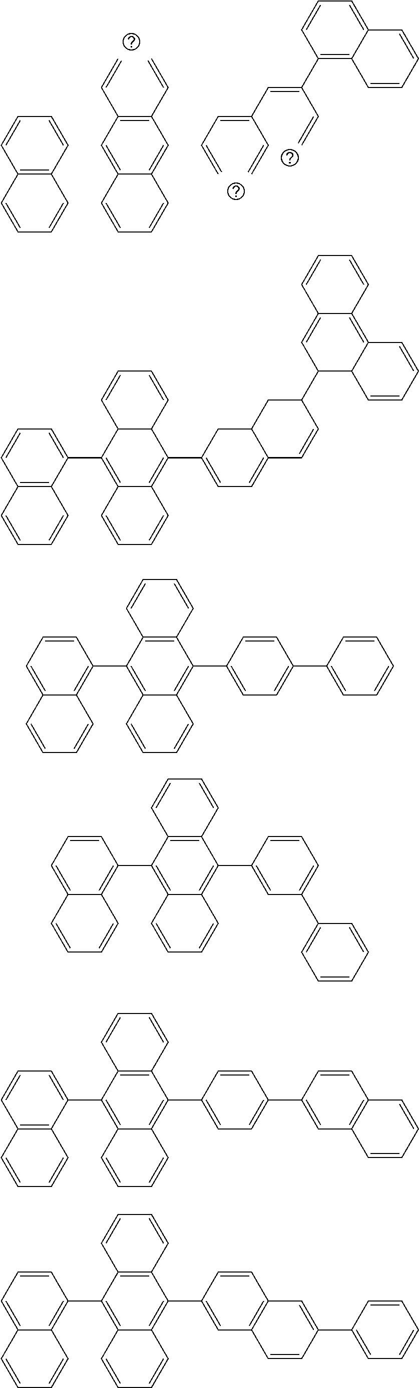

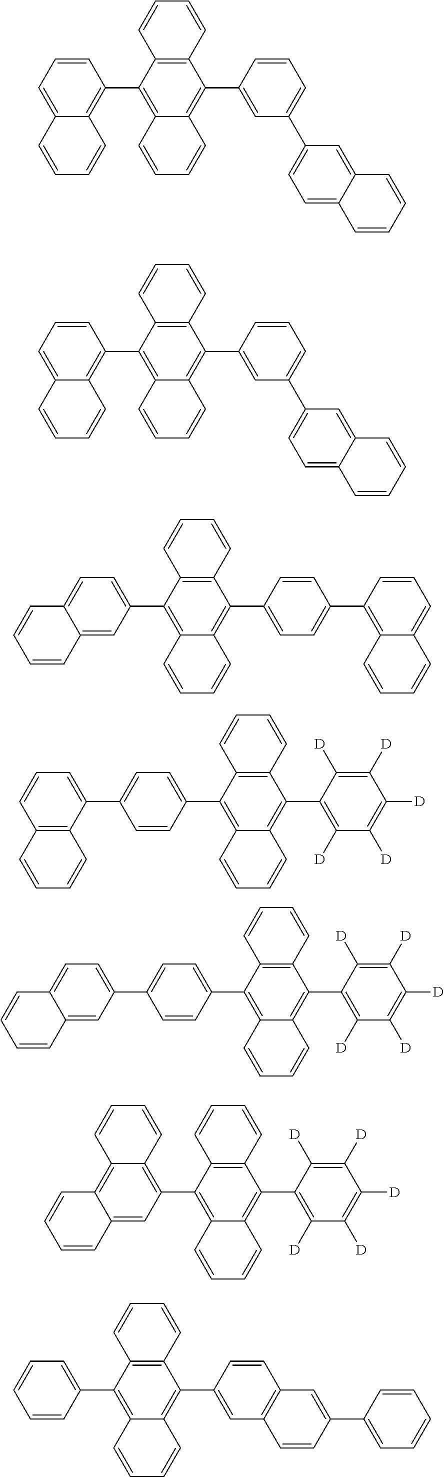

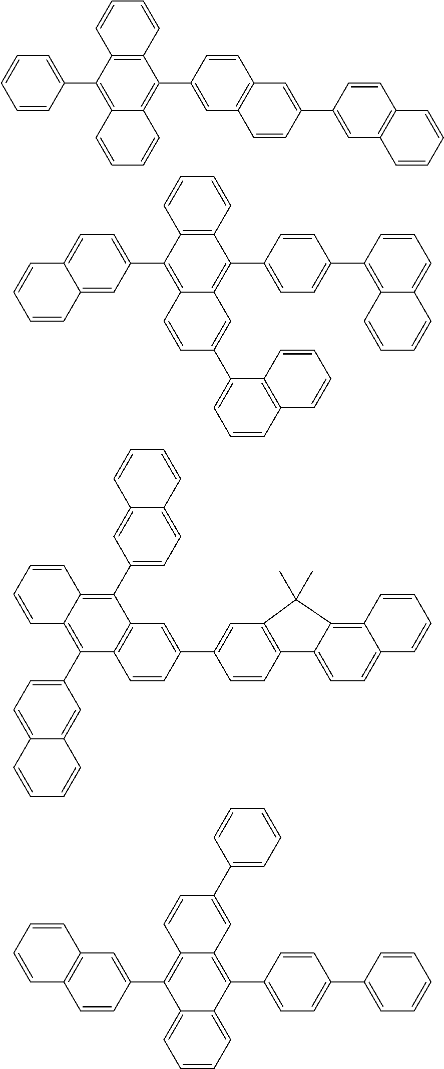

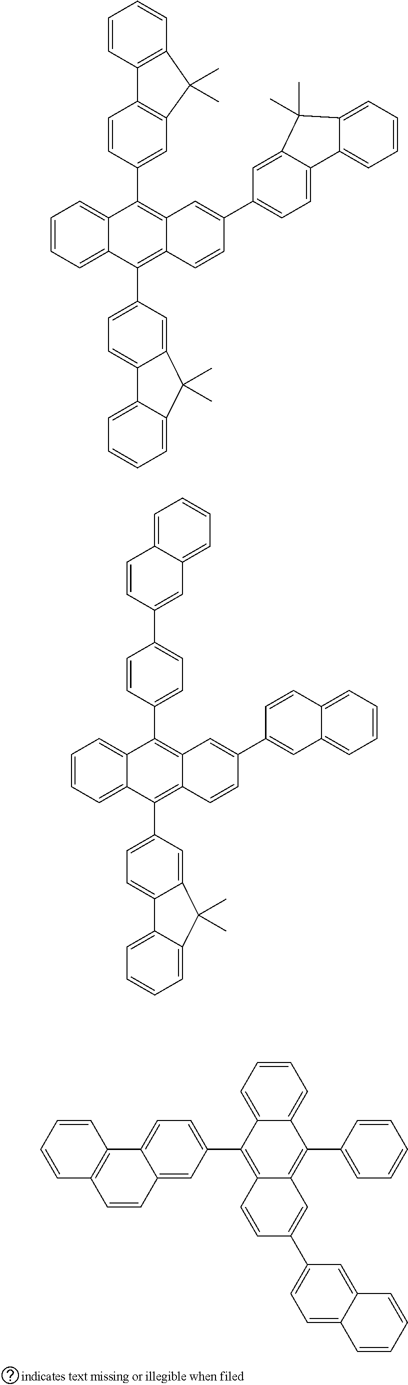

In some embodiments, an anthracene-based compound represented by Formula 401 below may be used as the host:

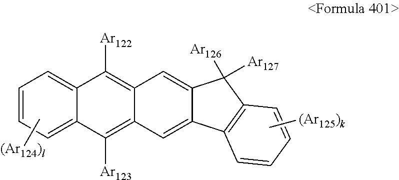

Ar₁₂₂ to Ar₁₂₅ in Formula 401 above may be defined as described above in conjunction with Ar₁₁₃ of Formula 400, and thus detailed descriptions thereof will not be provided here.

Ar₁₂₆ and Ar₁₂₇ in Formula 401 above may be each independently a C1-C10 alkyl group, for example, a methyl group, an ethyl group, or a propyl group.

In Formula 401, k and 1 may be each independently an integer from 0 to 4, for example, 0, 1, or 2.

For example, the anthracene-based compound of Formula 401 above may be one of the compounds represented by the following formulae, but is not limited thereto:

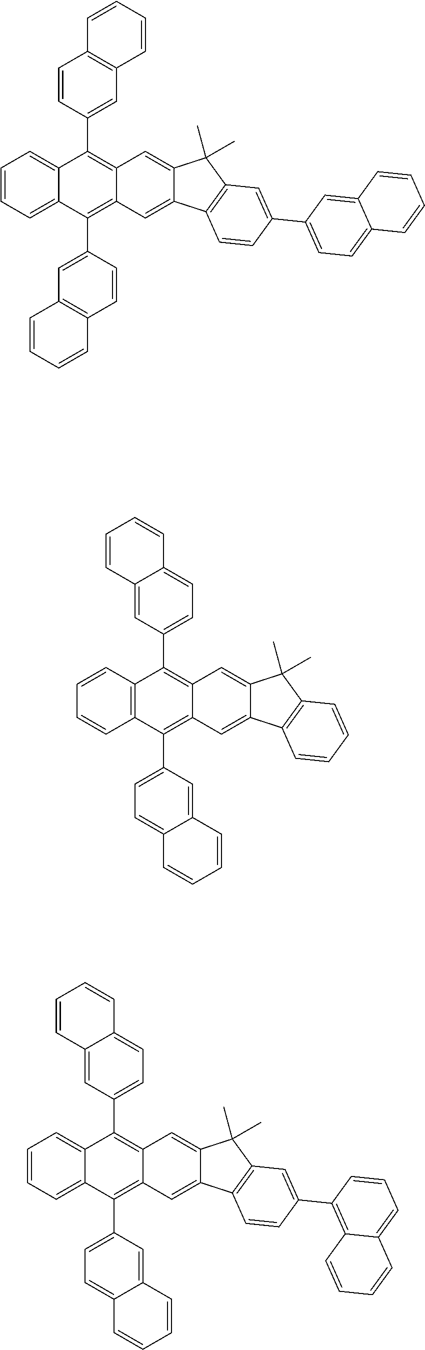

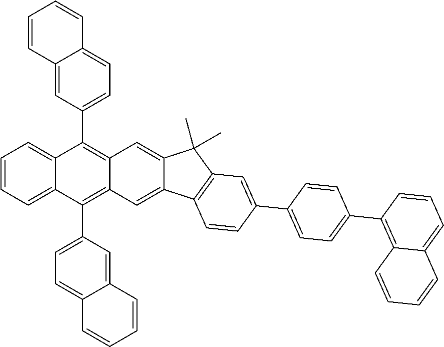 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device is a full color organic light-emitting device, the emission layer may be patterned into a red emission layer, a green emission layer, and a blue emission layer.

At least one of the red EML, the green EML, and the blue EML may include the compound of Formula 1 or a dopant below (ppy=phenylpyridine):

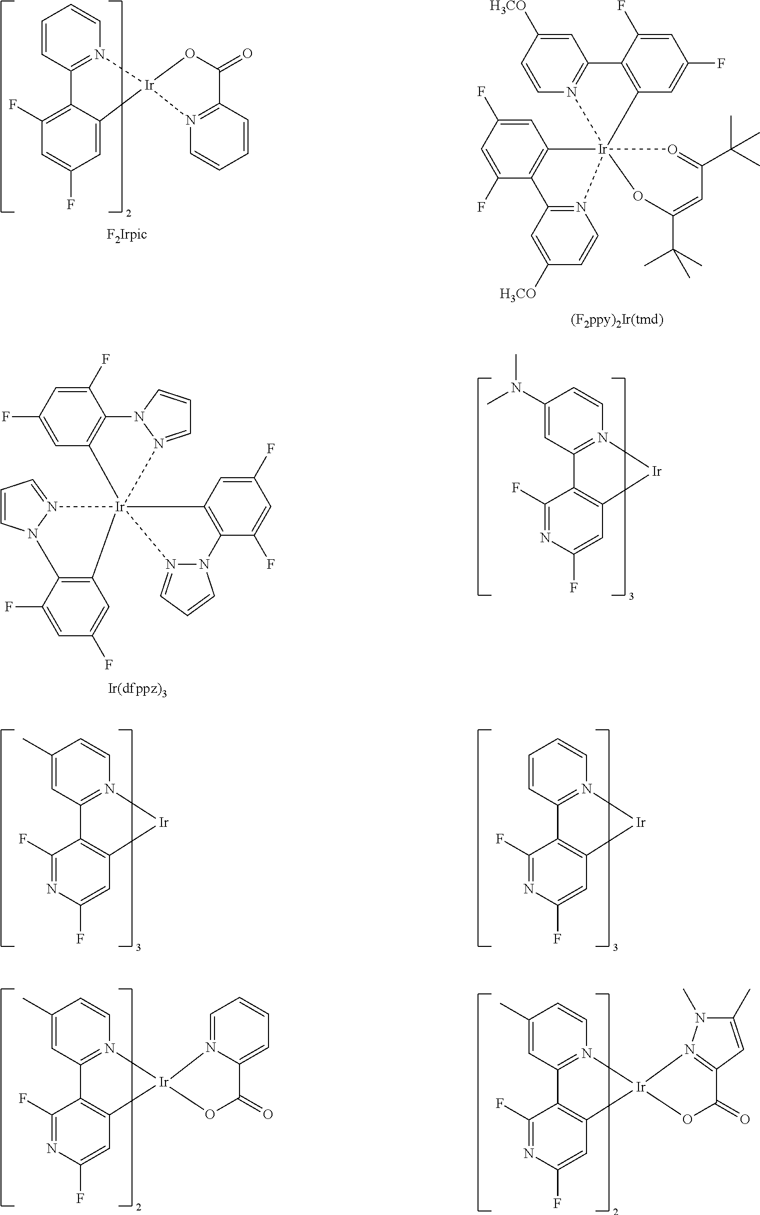

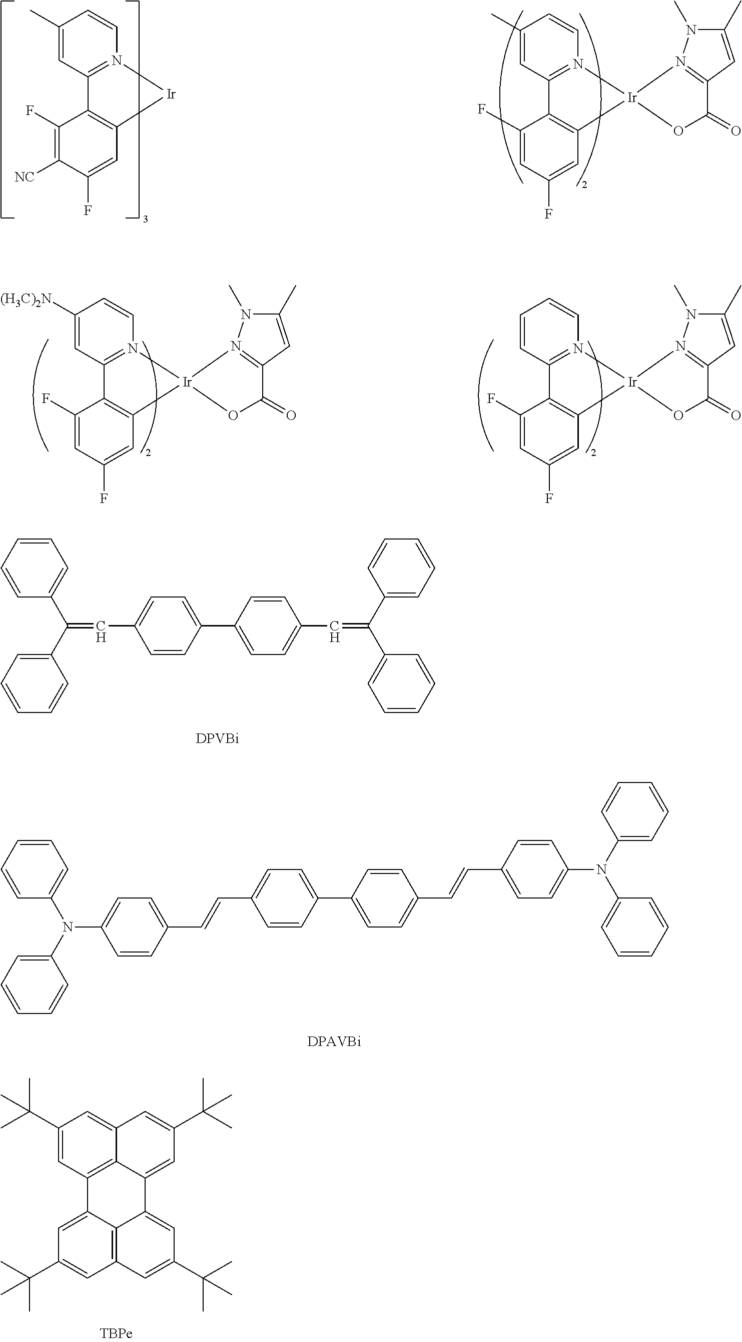

Non-limiting examples of the red dopant are compounds represented by the following formulae:

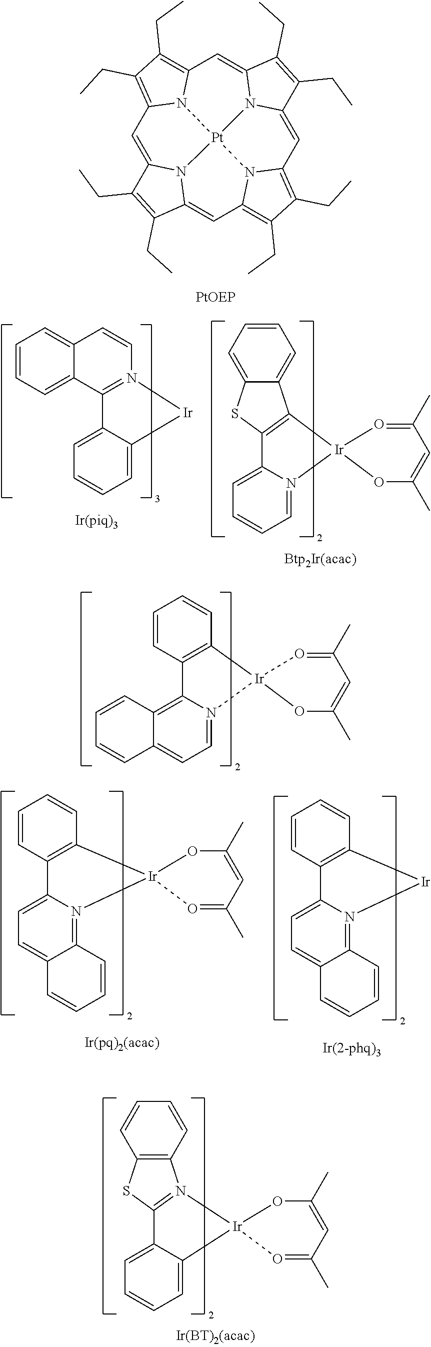

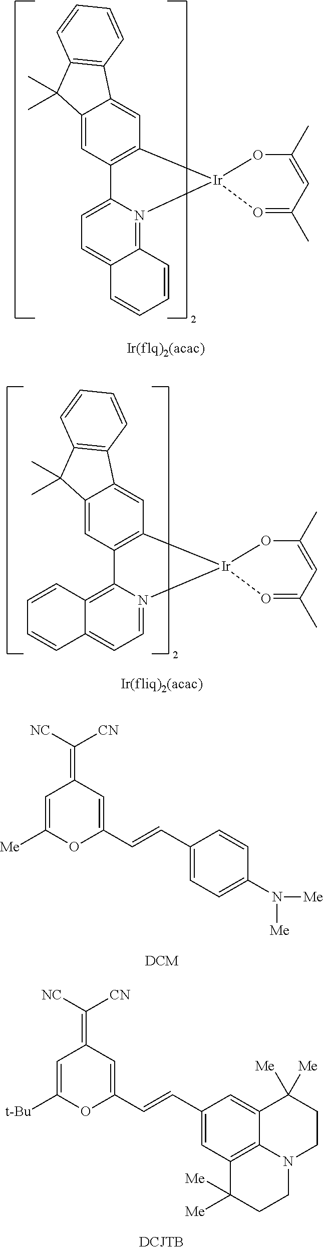

Non-limiting examples of the green dopant are compounds represented by the following formulae:

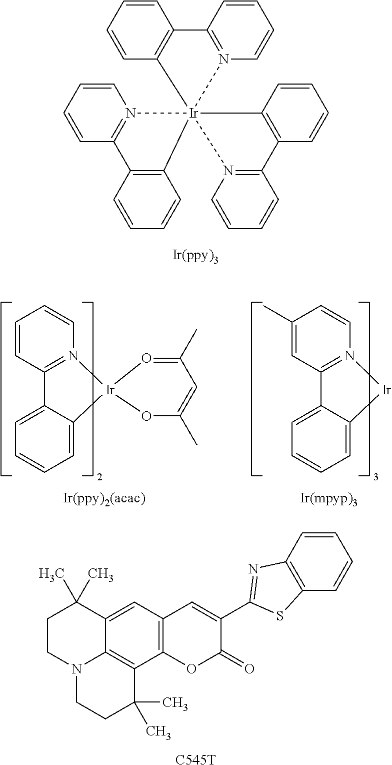

Non-limiting examples of the dopant that may be used in the EML are Pt complexes represented by the following formulae:

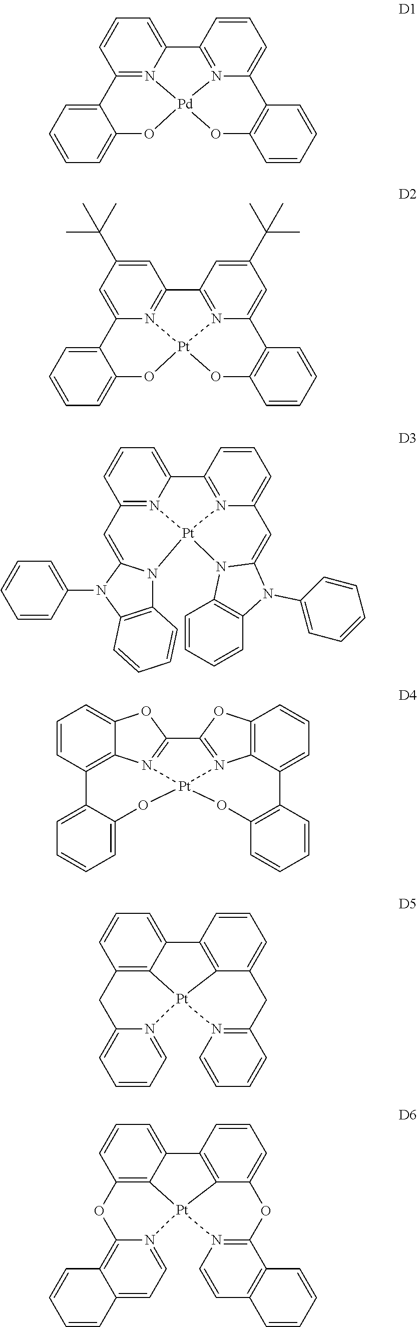

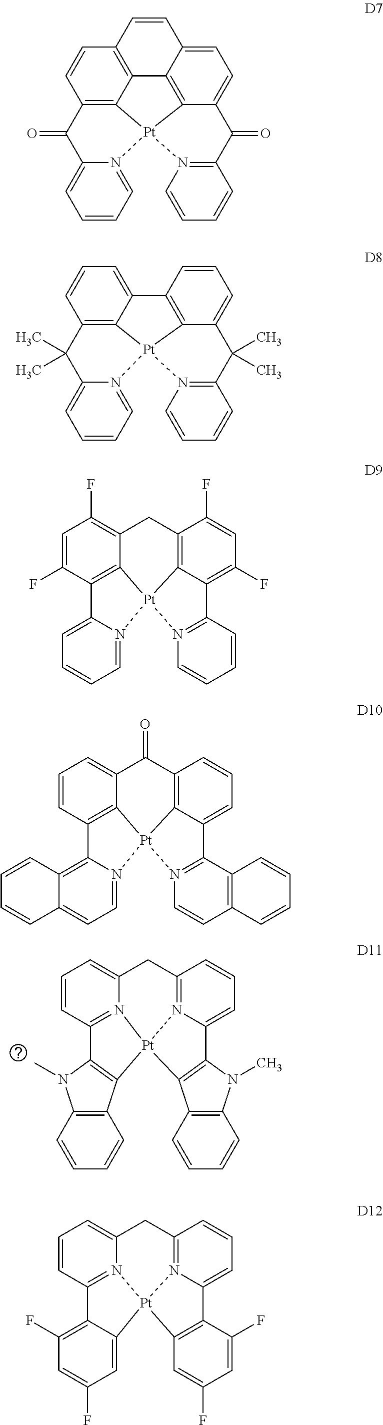

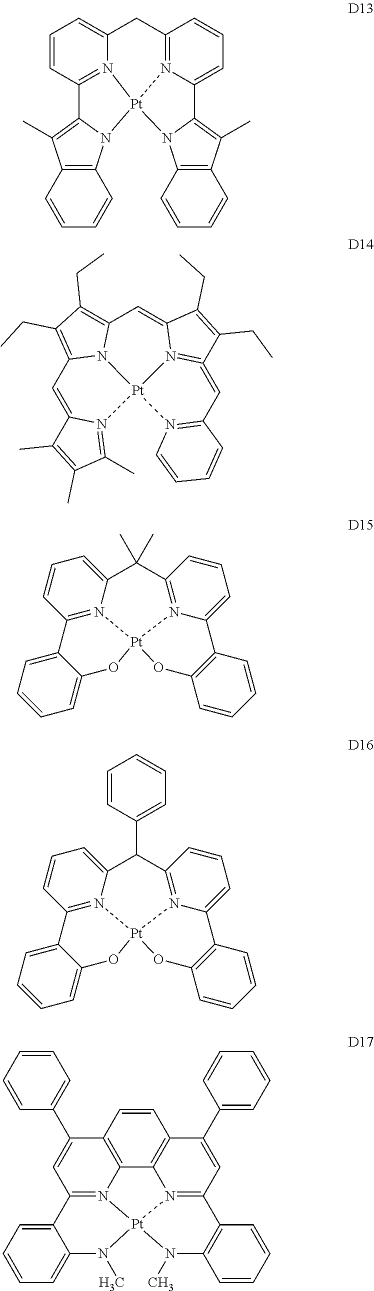

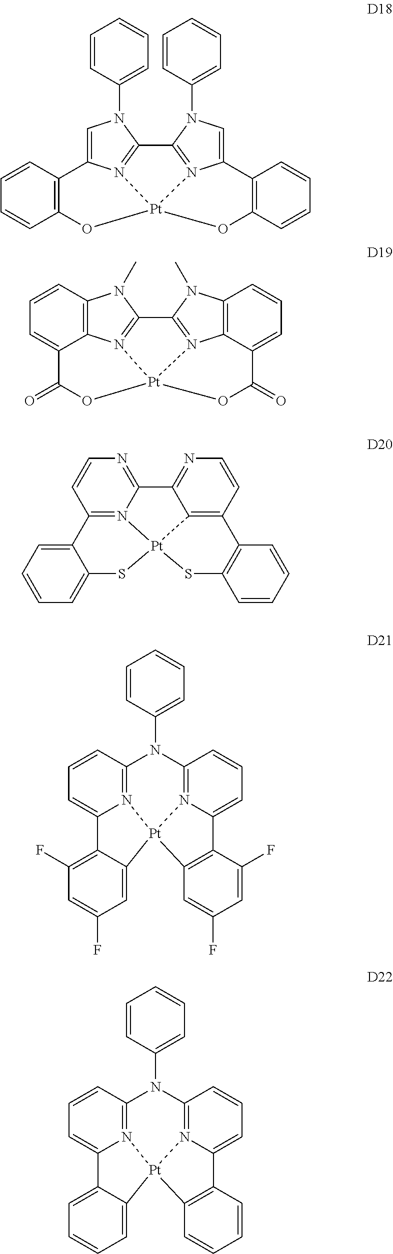

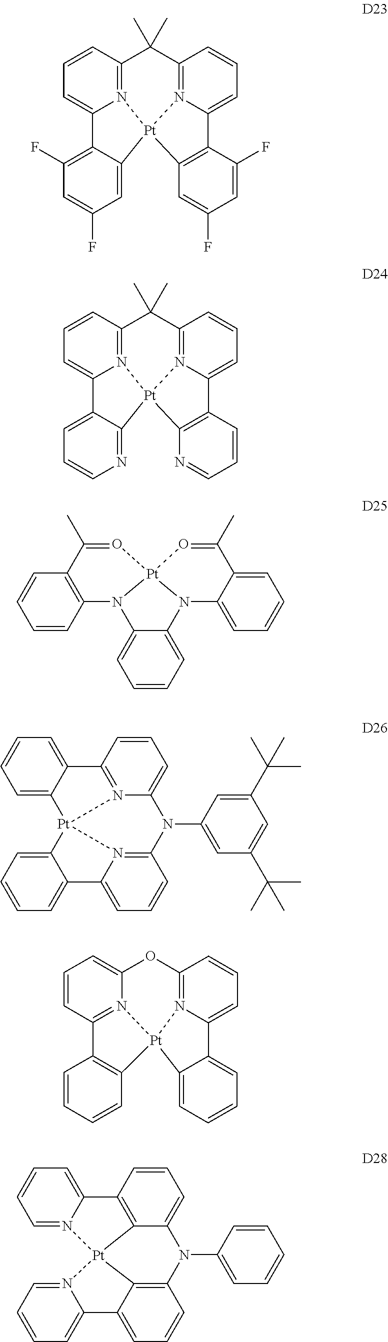

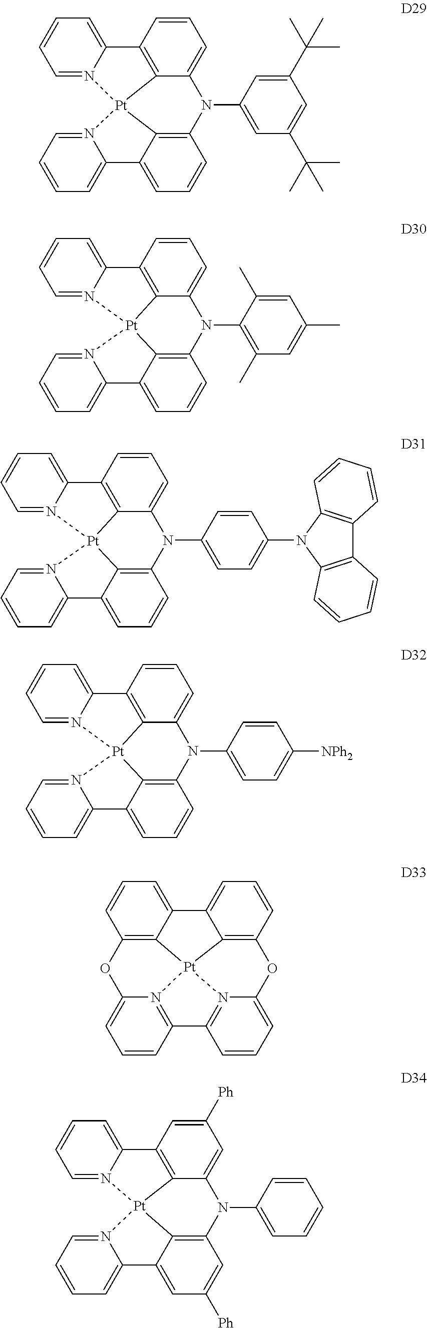

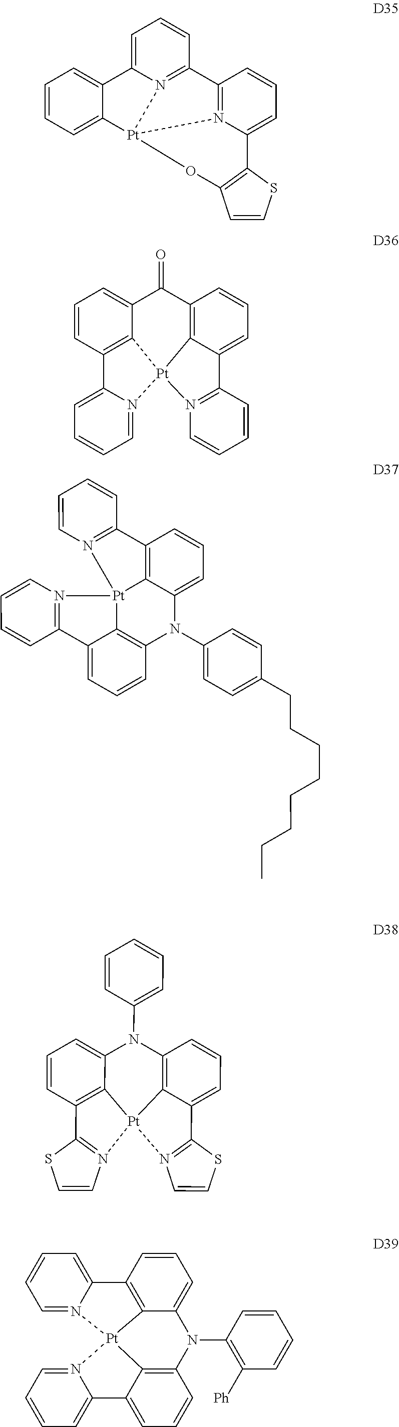

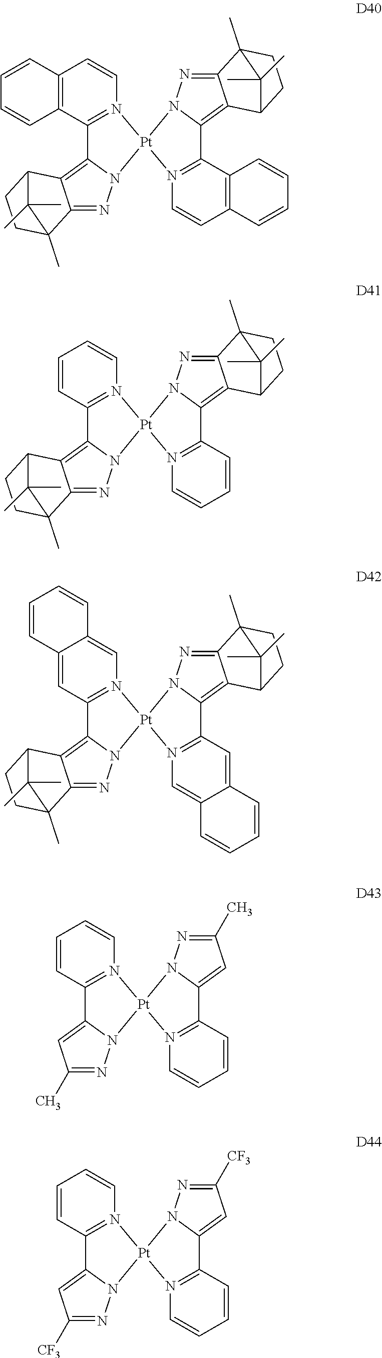

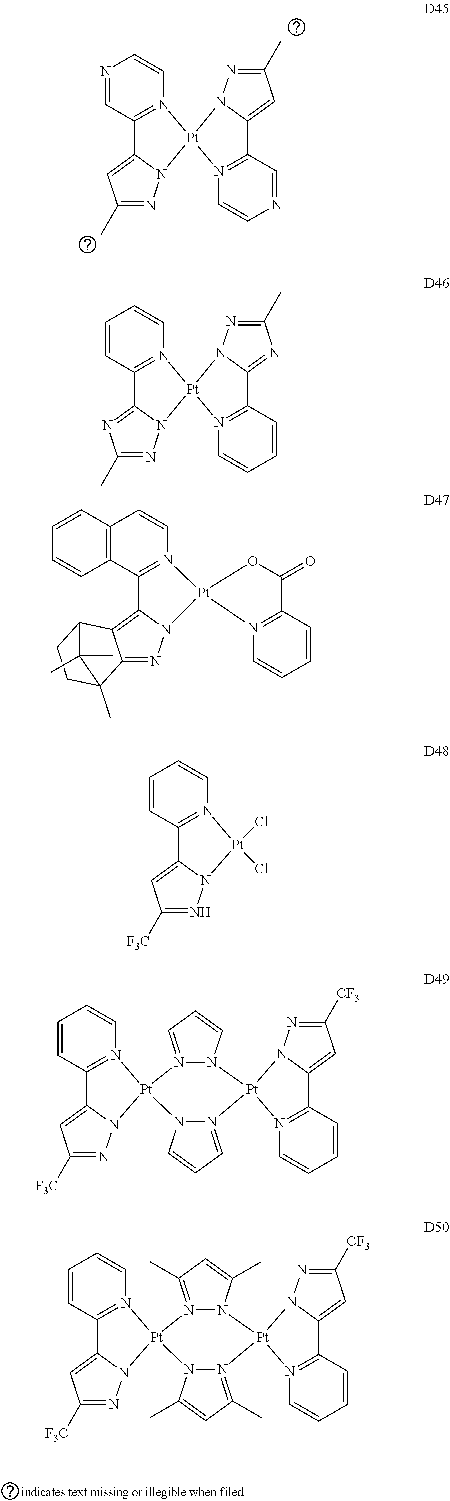

Non-limiting examples of the dopant that may be used in the EML are Os complexes represented by the following formulae:

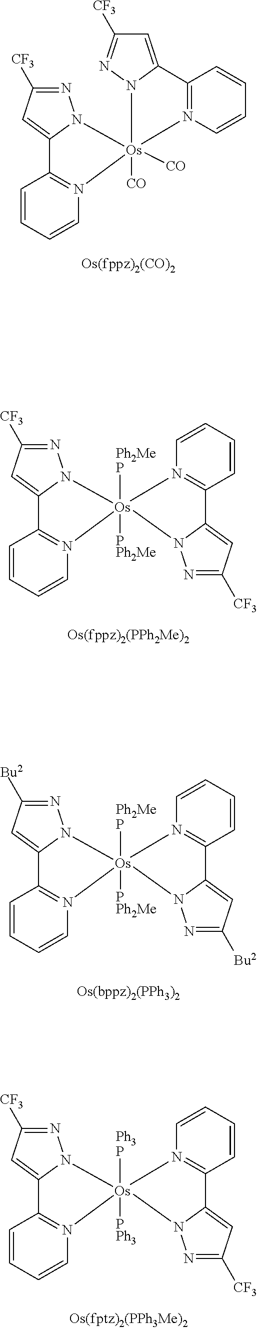

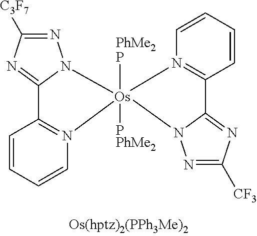

When the EML includes both a host and a dopant, the amount of the dopant may be from about 0.01 to about 15 parts by weight based on 100 parts by weight of the host. However, the amount of the dopant is not limited to this range.

The thickness of the EML may be from about 100 Å to about 1000 Å, and in some embodiments, from about 200 Å to about 600 Å. When the thickness of the EML is within these ranges, the EML may have good light emitting ability without a substantial increase in driving voltage.

Then, an ETL may be formed on the EML by vacuum deposition, spin coating, casting, or the like. When the ETL is formed using vacuum deposition or spin coating, the deposition and coating conditions may be similar to those for the formation of the HIL, though the deposition and coating conditions may vary according to a compound that is used to form the ETL. A material for forming the ETL may be the compound of Formula 1 above or any known material that can stably transport electrons injected from an electron injecting electrode (cathode). Non-limiting examples of materials for forming the ETL are a quinoline derivative, such as tris(8-quinolinorate)aluminum (Alq3), TAZ, BAlq, beryllium bis(benzoquinolin-10-olate (Bebq₂), 9,10-di(naphthalene-2-yl)anthracene (ADN), Compound 201, and Compound 202, but are not limited thereto.

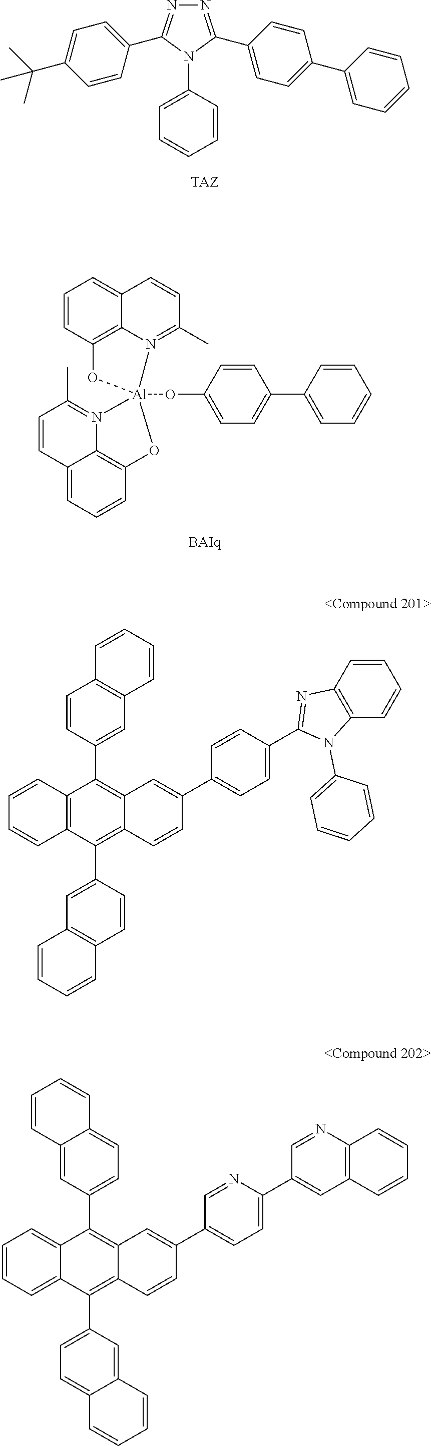

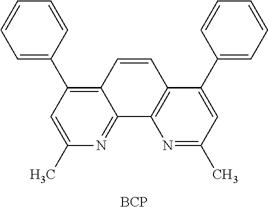 [SMILES: Cc1cc(-c2ccccc2)c2ccc3c(-c4ccccc4)cc(C)nc3c2n1 ; "BCP"]

The thickness of the HTL may be from about 100 Å to about 1000 Å, and in some embodiments, from about 150 Å to about 500 Å. When the thickness of the ETL is within these ranges, the ETL may have satisfactory electron transporting ability without a substantial increase in driving voltage.

In some embodiments the ETL may further include a metal-containing material, in addition to any known electron-transporting organic compound.

The metal-containing material may include a lithium (Li) complex. Non-limiting examples of the Li complex are lithium quinolate (LiQ) and Compound 203 below:

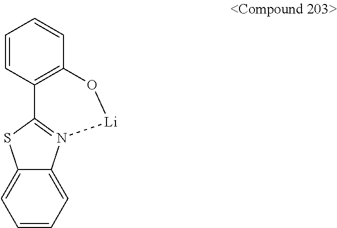

Then, an EIL, which facilitates injection of electrons from the cathode, may be formed on the ETL. Any suitable electron-injecting material may be used to form the EIL.

Non-limiting examples of materials for forming the EIL are LiF, NaCl, CsF, Li₂O, and BaO, which are known in the art. The deposition and coating conditions for forming the EIL 18 may be similar to those for the formation of the HIL, though the deposition and coating conditions may vary according to the material that is used to form the EIL 18.

The thickness of the EIL may be from about 1 Å to about 100 Å, and in some embodiments, from about 3 Å to about 90 Å. When the thickness of the EIL is within these ranges, the EIL may have satisfactory electron injection ability without a substantial increase in driving voltage.

Finally, the second electrode is disposed on the organic layer. The second electrode may be a cathode that is an electron injection electrode. material for forming the second electrode may be a metal, an alloy, an electro-conductive compound, which have a low work function, or a mixture thereof. In this regard, the second electrode may be formed of lithium (Li), magnesium (Mg), aluminum (Al), aluminum (Al)-lithium (Li), calcium (Ca), magnesium (Mg)-indium (In), magnesium (Mg)-silver (Ag), or the like, and may be formed as a thin film type transmission electrode. In some embodiments, to manufacture a top-emission light-emitting device, the transmission electrode may be formed of indium tin oxide (ITO) or indium zinc oxide (IZO).

Although the organic light-emitting device of FIG. 1 is described above, the present invention is not limited thereto.

When a phosphorescent dopant is used in the EML, a HBL may be formed between the HTL and the EML or between the H-functional layer and the EML by using vacuum deposition, spin coating, casting, Langmuir-Blodgett (LB) deposition, or the like, in order to prevent diffusion of triplet excitons or holes into the ETL. When the HBL is formed using vacuum deposition or spin coating, the conditions for deposition and coating may be similar to those for the formation of the HIL, although the conditions for deposition and coating may vary according to the material that is used to form the HBL. Any known hole-blocking material may be used. Non-limiting examples of hole-blocking materials are oxadiazole derivatives, triazole derivatives, and phenanthroline derivatives. For example, bathocuproine (BCP) represented by the following formula may be used as a material for forming the HBL.

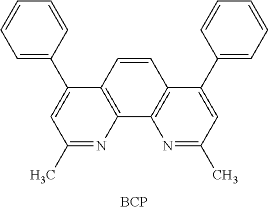 [SMILES: Cc1cc(-c2ccccc2)c2ccc3c(-c4ccccc4)cc(C)nc3c2n1 ; "BCP"]

The thickness of the HBL may be from about 20 Å to about 1000 Å, and in some embodiments, from about 30 Å to about 300 Å. When the thickness of the HBL is within these ranges, the HBL may have improved hole blocking ability without a substantial increase in driving voltage.

According to embodiments of the present invention, the organic light-emitting device may be included in various types of flat panel display devices, such as in a passive matrix organic light-emitting display device or in an active matrix organic light-emitting display device. In particular, when the organic light-emitting device is included in an active matrix organic light-emitting display device including a thin-film transistor, the first electrode on the substrate may function as a pixel electrode, electrically connected to a source electrode or a drain electrode of the thin-film transistor. Moreover, the organic light-emitting device may also be included in flat panel display devices having double-sided screens.

In some embodiments the organic layer of the organic light-emitting device may be formed of the compound of Formula 1 by using a deposition method or may be formed using a wet method of coating a solution of the compound of Formula 1.

Hereinafter, the present invention will be described in detail with reference to the following synthesis examples and other examples. However, these examples are for illustrative purposes only and are not intended to limit the scope of the present invention.

### EXAMPLES

### Synthesis Example 1

### Synthesis of Compound 12

Compound 12 was synthesized according to Reaction Scheme 1 below:

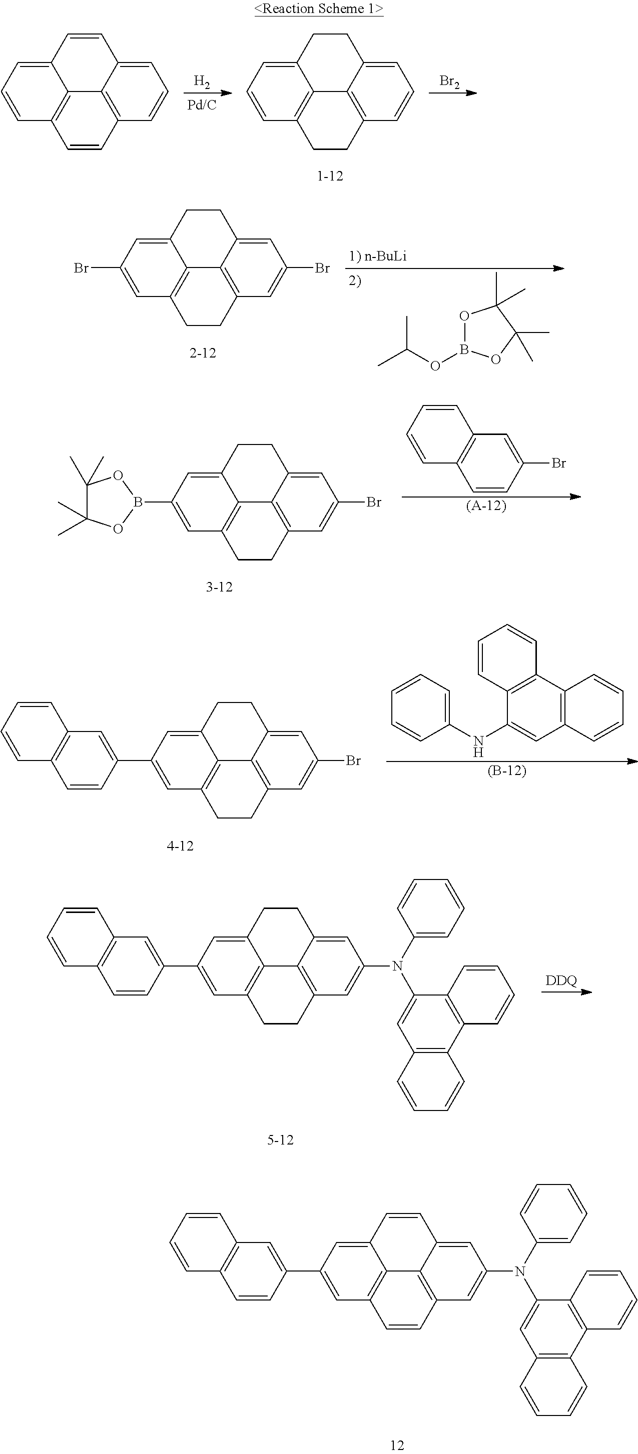

Synthesis of Intermediate 1-12

100 mg (0.2 mmol) of 10% palladium was added to a reactant including 4.04 g (20 mmol) of pyran dissolved in 50 ml of methylene chloride (MC). The reaction solution was stirred in a hydrogen atmosphere for about 12 hours, followed by filtering the solution through Celite to remove palladium precipitate and removing the solvent under vacuum, to obtain 3.50 g of Intermediate 1-12 (yield: 85%). This compound was identified using MS/FAB.

C₁₆H₁₄: calc. 206.10. found 206.35

Synthesis of Intermediate 2-12

3.56 g (20 mmol) of N-Bromosuccinimide (NBS) was completely dissolved in 50 ml of dimethylformamide (DMF), and 2.06 g (10 mmol) of Intermediate 1-12 was added to the solution, and then stirred at room temperature for about 24 hours. The reaction solution was extracted twice with 50 ml of water and 50 ml of dichloromethane. The organic phase was collected and was dried using magnesium sulfate to evaporate the solvent. The residue was separated and purified using silica gel column chromatography to obtain 2.51 g of Intermediate 2-12 (yield: 69%). This compound was identified using MS/FAB.

C₁₆H₁₂Br₂: calc. 361.93. found 362.08

Synthesis of Intermediate 3-12

3.64 g (10 mmol) of Intermediate 2-12 and 6.25 ml (10 mmol) of n-BuLi (1.60 M hexane solution) were reacted in tetrahydrofuran (THF) at about −78° C. for 3 hours. Then, 2.04 g (12 mmol) of 2-isopropylboron pinacol ester was added to the reaction solution at about −78° C., and then stirred at room temperature for about 12 hours, followed by adding 5 ml of 1N HCl (aq). After separating the organic phase of the reaction solution, the aqueous phase was extracted twice with 100 ml of dichloromethane. The organic phase of the extraction and the separated organic phase were collected and dried using magnesium sulfate to evaporate the solvent. The residue was separated and purified using silica gel column chromatography to obtain 3.20 g of Intermediate 3-12 (yield: 78%). This compound was identified using MS/FAB.

C₂₂H₂₄BBrO₂: calc. 410.10. found 410.32

Synthesis of Intermediate 4-12

4.11 g (10 mmol) of Intermediate 3-12, 2.07 g (10 mmol) of 2-naphthylboronic acid (Compound A-12), 0.29 g (0.25 mmol) of tetrakis(triphenylphosphine)palladium (Pd(PPh₃)₄), and 0.62 g (4.48 mmol) of K₂CO₃ were dissolved in a mixed solution 60 ml of THF/H₂O (2:1 by volume), and then stirred at about 70° C. for about 5 hours. After the reaction solution was cooled to room temperature, 40 ml of water was added to the reaction solution, which was then extracted three times with 50 ml of ethylether. The organic phase was collected and was dried using magnesium sulfate to evaporate the solvent. The residue was separated and purified using silica gel column chromatography to obtain 3.04 g of Intermediate 4-12 (yield: 74%). This compound was identified using MS/FAB.

C₂₆H₁₉Br: calc. 410.06. found 410.15

Synthesis of Intermediate 5-12

In a nitrogen atmosphere, 2.87 g (7.0 mmol) of Intermediate 4-12, 1.89 g (7 mmol) of phenanthrene-9-yl-phenyl-amine, 2.0 g (21 mmol) of t-BuONa, 260 mg (0.28 mmol) of Pd₂(dba)₃, and 56 mg (0.28 mmol) of P(t-Bu)₃ were dissolved in 50 ml of toluene, and then stirred at about 90° C. for about 3 hours. After the reaction solution was cooled to room temperature, the reaction solution was extracted three times with 50 ml of distilled water and diethyl ether. The organic phase was collected and was dried using magnesium sulfate to evaporate the solvent. The residue was separated and purified using silica gel column chromatography to obtain 2.81 g of Intermediate 5-12 (yield: 67%). This compound was identified using HR-MS.

C₄₆H₃₃N: calc. 599.26. found 599.45

Synthesis of Compound 12

2.50 g (11 mmol) of 2,3-dichloro-5,6-dicyano-p-quinone was added to a reactant including 5.99 g (10 mmol) of Intermediate 5-12 dissolved in 50 ml of MC. The reaction solution was stirred for about 12 hours, followed by filtering the solution through Celite to remove palladium precipitate and removing the solvent under vacuum, to obtain 4.52 g of Compound 12 (yield: 76%). This compound was identified using MS/FAB.

C₄₆H₂₉N: calc. 595.23. found 595.38

Synthesis of Compound 21

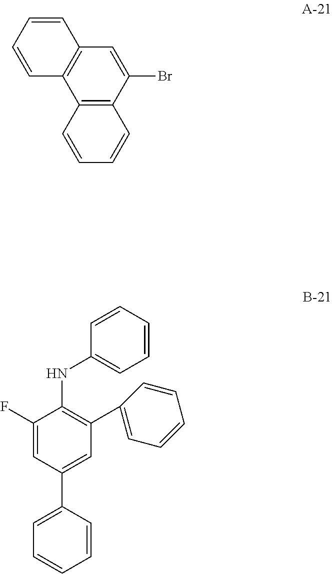 [SMILES: Brc1cc2ccccc2c2ccccc12 ; Fc1cc(-c2ccccc2)cc(-c2ccccc2)c1Nc1ccccc1]

Compound 21 was synthesized in the same manner as in Synthesis Example 1, except that Compound A-21 was used, instead of Compound A-12 and Compound B-21 was used, instead of Compound B-12 in the synthesis of Compound 12. This compound was identified using ¹H NMR and MS/FAB.

C₂₄H₂₄BNO₂; M⁺322.1

Synthesis of Compound 28

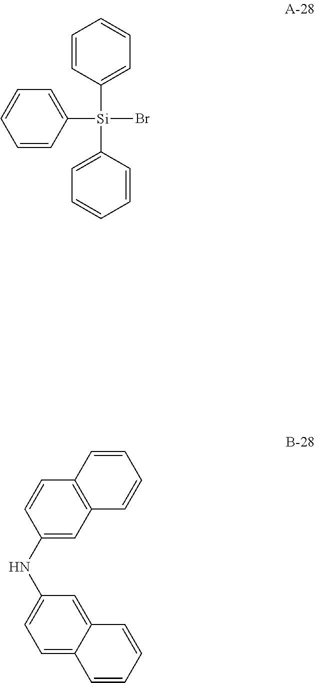 [SMILES: Br[Si](c1ccccc1)(c1ccccc1)c1ccccc1 ; c1ccc2cc(Nc3ccc4ccccc4c3)ccc2c1]

Compound 28 was synthesized in the same manner as in Synthesis Example 1, except that Compound A-28 was used, instead of Compound A-12 and Compound B-28 was used, instead of Compound B-12 in the synthesis of Compound 12. This compound was identified using ¹H NMR and MS/FAB.

C₅₄H₃₇NSi: calc. 727.27. found 728.33

Synthesis of Compound 42

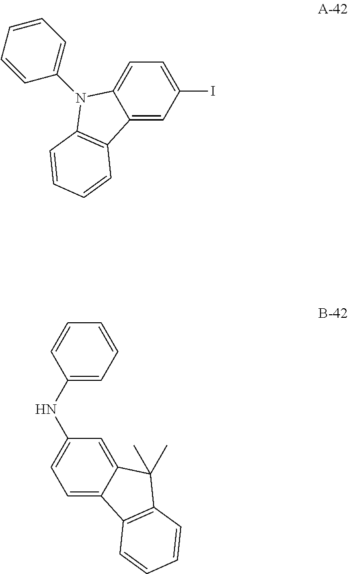 [SMILES: Ic1ccc2c(c1)c1ccccc1n2-c1ccccc1 ; CC1(C)c2ccccc2-c2ccc(Nc3ccccc3)cc21]

Compound 42 was synthesized in the same manner as in Synthesis Example 1, except that Compound A-42 was used, instead of Compound A-12, and Compound B-42 was used, instead of Compound B-12 in the synthesis of Compound 12. This compound was identified using ¹H NMR and MS/FAB.

C₅₅H₃₈N₂: calc. 726.30. found 727.42

Synthesis of Compound 46

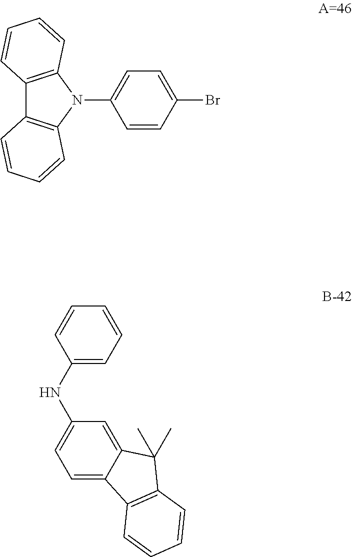 [SMILES: Brc1ccc(-n2c3ccccc3c3ccccc32)cc1 ; CC1(C)c2ccccc2-c2ccc(Nc3ccccc3)cc21]

Compound 46 was synthesized in the same manner as in Synthesis Example 1, except that Compound A-46 was used, instead of Compound A-12, and Compound B-42 was used, instead of Compound B-12 in the synthesis of Compound 12. This compound was identified using ¹H NMR and MS/FAB.

C₅₅H₃₈N₂: calc. 726.30. found 727.45

Synthesis of Compound 53

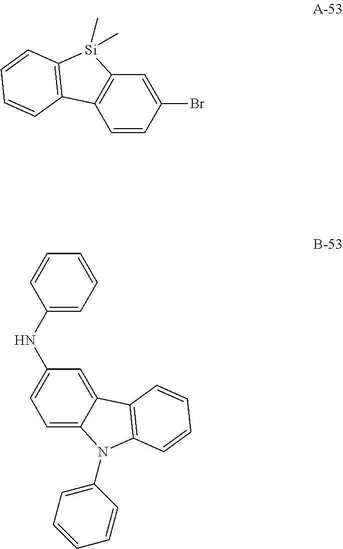 [SMILES: C[Si]1(C)c2ccccc2-c2ccc(Br)cc21 ; c1ccc(Nc2ccc3c(c2)c2ccccc2n3-c2ccccc2)cc1]

Compound 53 was synthesized in the same manner as in Synthesis Example 1, except that Compound A-53 was used, instead of Compound A-12, and Compound B-53 was used, instead of Compound B-12 in the synthesis of Compound 12. This compound was identified using ¹H NMR and MS/FAB.

C₅₄H₃₈N₂Si: calc. 742.28. found 743.40

Synthesis of Compound 54

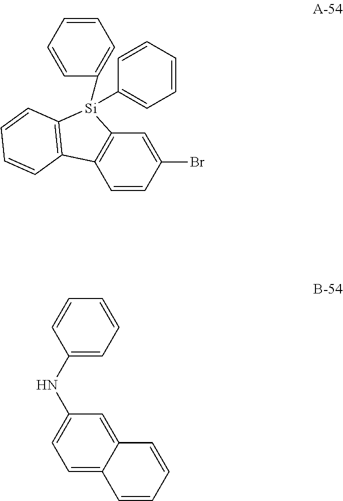 [SMILES: Brc1ccc2c(c1)[Si](c1ccccc1)(c1ccccc1)c1ccccc1-2 ; c1ccc(Nc2ccc3ccccc3c2)cc1]

Compound 54 was synthesized in the same manner as in Synthesis Example 1, except that Compound A-54 was used, instead of Compound A-12, and Compound B-54 was used, instead of Compound B-12 in the synthesis of Compound 12. This compound was identified using ¹H NMR and MS/FAB.

C₅₆H₃₇NSi: calc. 751.27. found 752.39

Synthesis of Compound 56

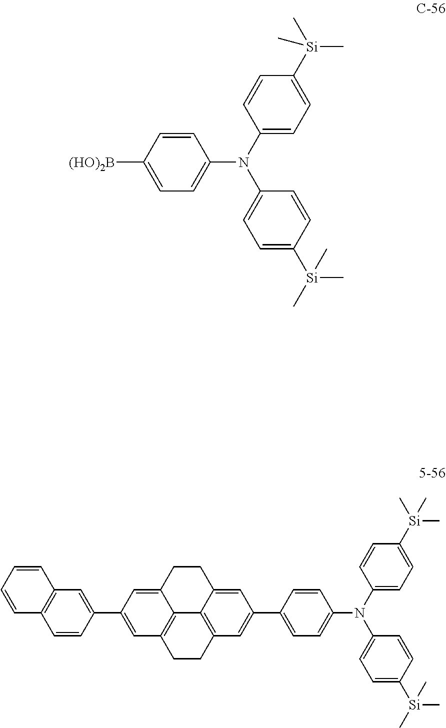 [SMILES: C[Si](C)(C)c1ccc(N(c2ccc(B(O)O)cc2)c2ccc([Si](C)(C)C)cc2)cc1 ; C[Si](C)(C)c1ccc(N(c2ccc(-c3cc4c5c(c3)CCc3cc(-c6ccc7ccccc7c6)cc(c3-5)CC4)cc2)c2ccc([Si](C)(C)C)cc2)cc1]

Intermediate 5-56 was synthesized in the same manner as in the synthesis of Intermediate 4-12 of Synthesis Example 1, except that Intermediate 4-12 was used, instead of

Compound A-12, and Compound C-56 was used, instead of Intermediate 3-12. Compound 56 was synthesized in the same manner as in Synthesis Example 1, except that Intermediate 5-56 was used, instead of Intermediate 5-12 in the synthesis of Compound 12. This compound was identified using ¹H NMR and MS/FAB.

C₅₆H₄₅NSi₂: calc. 715.31. found 716.52

Synthesis of Compound 68

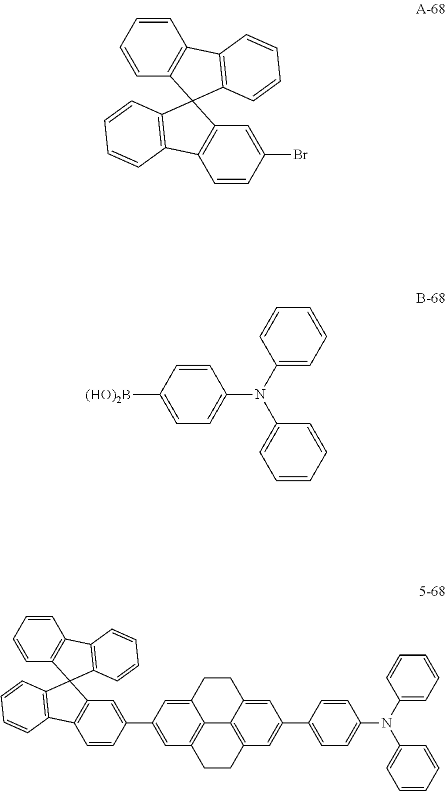 [SMILES: Brc1ccc2c(c1)C1(c3ccccc3-c3ccccc31)c1ccccc1-2 ; OB(O)c1ccc(N(c2ccccc2)c2ccccc2)cc1 ; c1ccc(N(c2ccccc2)c2ccc(-c3cc4c5c(c3)CCc3cc(-c6ccc7c(c6)C6(c8ccccc8-c8ccccc86)c6ccccc6-7)cc(c3-5)CC4)cc2)cc1]

Intermediate 5-68 was synthesized in the same manner as in the synthesis of Intermediate 4-12 of Synthesis Example 1, except that Compound A-68 was used, instead of Compound A-12, and Compound B-68 was used, instead of Intermediate 3-12. Compound 68 was synthesized in the same manner as in Synthesis Example 1, except that Intermediate 5-68 was used, instead of Intermediate 5-12 in the synthesis of Compound 12. This compound was identified using ¹H NMR and MS/FAB.

C₅₉H₃₇N: calc. 759.93. found 760.85

Additional compounds were synthesized using appropriate intermediate materials according to the synthetic pathways and the methods described as above, and were identified using ¹H NMR and MS/FAB. The results are shown in Table 1 below.

Synthetic pathways and source materials for other compounds not in Table 1 will be obvious to one of ordinary skill in the art based on the synthetic pathways and source materials described above.

| | | TABLE | |
|---|---|---|---|
| | | MS/FAB | |
| Compound | ¹H NMR (CDCl₃, 400 MHz) | found | calc. |
| 2 | δ = 8.29 (s, 2H), 7.83 (s, 1H), 7.81 (s, 1H), 7.78 (m, 1H), | 546.31 | 545.21 |
| | 7.76-7.73 (m, 5H), 7.62 (s, 1H), 7.60 (s, 1H), 7.57-7.53 (m, | | |
| | 7H), 7.18-7.17 (d, 1H), 7.15 (d, 1H) | | |
| 3 | δ = 8.30 (s, 2H), 8.10-8.08 (ss, 2H), 7.78-7.76 (m, 1H), | 511.35 | 510.21 |
| | 7.74-7.72 (ss, 2H), 7.60-7.58 (ss, 1H), 7.42 (s, 2H), 7.36-7.30 (m, | | |
| | 1H), 7.14-7.06 (m, 4H), 6.67-6.63 (m, 2H), 6.48-6.47 (d, 1H), | | |
| | 6.21-6.18 (m, 2H), 1.61 (s, 6H) | | |
| 4 | δ = 8.59-8.57 (m, 1H), 8.19-8.17 (m, 1H), 8.00-7.96 (m, 3H), | 542.55 | 541.22 |
| | 7.83-7.81 (ss, 2H), 7.71-7.66 (m, 3H), 7.59-7.53 (m, 2H), | | |
| | 7.43-7.39 (t, 2H), 7.36 (s, 2H), 7.08-7.05 (m, 2H), | | |
| | 6.65-6.61 (m, 2H), 5.99-5.97 (m, 2H), 0.36 (s, 9H) | | |
| 8 | δ = 8.37 (s, 2H), 8.24 (s, 1H), 8.02-8.00 (m, 1H), | 666.44 | 665.25 |
| | 7.96-7.94 (m, 2H), 7.85-7.82 (ss, 3H), 7.72-7.70 (m, 4H), 7.65-7.60 (m, | | |
| | 4H), 7.55-7.50 (m, 7H), 7.44-7.40 (m, 2H), 7.16-7.13 (dd, | | |
| | 1H), 7.07-7.04 (m, 2H), 6.63-6.60 (m, 1H), 6.07-6.05 (m, 2H) | | |
| 12 | δ = 8.59-8.57 (m, 1H), 8.37 (s, 2H), 8.24 (m, 1H), | 596.33 | 595.23 |
| | 8.19-8.17 (m, 1H), 8.02-7.94 (m, 4H), 7.85-7.82 (ss, 3H), 7.71-7.65 (m, | | |
| | 3H), 7.61-7.51 (m, 5H), 7.43 (t, 1H), 7.36 (s, 2H), | | |
| | 7.08-7.04 (m, 2H), 6.67-6.61 (m, 2H), 5.99-5.97 (m, 2H) | | |
| 13 | δ = 8.30 (s, 2H), 8.20-8.17 (ss, 2H), 8.12-8.10 (m, 2H), | 494.25 | 493.18 |
| | 7.92-7.90 (m, 1H), 7.77-7.74 (m, 2H), 7.71 (s, 2H), 7.69 (s, 2H), | | |
| | 7.51-7.47 (t, 1H), 7.44-7.41 (m, 1H), 7.39-7.37 (m, 2H), | | |
| | 7.36-7.33 (m, 2H), 7.30-7.21 (m, 3H), 7.16-7.13 (m, 1H) | | |
| 15 | δ = 8.15-8.10 (m, 6H), 8.00-7.97 (dd, 1H), 7.81-7.79 (m, 1H), | 560.37 | 559.23 |
| | 7.76 (d, 1H), 7.73 (s, 1H), 7.71 (s, 2H), 7.69 (s, 1H), 7.67 (s, | | |
| | 1H), 7.41-7.37 (m, 2H), 7.36-7.34 (m, 2H), 7.30-7.26 (m, | | |
| | 3H), 7.15-7.09 (m, 3H), 1.57 (s, 6H) | | |
| 17 | δ = 8.65-8.63 (m, 1H), 8.55-8.53 (m, 1H), 8.40 (s, 2H), | 602.49 | 601.28 |
| | 7.93-7.90 (m, 3H), 7.81-7.79 (m, 1H), 7.68-7.50 (m, 8H), | | |
| | 7.18-7.14 (m, 1H), 6.78 (s, 2H), 6.32 (s, 2H), 2.32 (s, 12H) | | |
| 19 | δ = 8.65-8.63 (m, 1H), 8.55-8.53 (m, 1H), 8.40 (s, 2H), | 601.42 | 600.26 |
| | 7.93 (s, 1H), 7.91-7.90 (m, 2H), 7.81-7.71 (m, 3H), 7.67-7.50 (m, | | |
| | 9H), 7.44 (s, 2H), 7.40-7.38 (m, 1H), 7.18-7.13 (m, 2H) | | |
| 21 | δ = 8.64-8.63 (m, 1H), 8.55-8.53 (m, 1H), 8.40 (s, 2H), | 716.35 | 715.27 |
| | 7.93 (s, 1H), 7.90 (m, 2H), 7.81-7.79 (m, 1H), 7.75 (s, 1H), | | |
| | 7.70-7.59 (m, 9H), 7.55-7.50 (m, 6H), 7.44-7.40 (m, 3H), | | |
| | 7.18-7.05 (m, 4H), 6.63-6.60 (m, 1H), 6.07-6.05 (m, 2H) | | |
| 27 | δ = 9.17 (ss, 1H), 8.84-8.82 (ss, 1H), 8.50-8.48 (m, 1H), | 644.40 | 643.27 |
| | 8.16-8.07 (m, 4H), 7.99-7.97 (m, 2H), 7.87-7.82 (m, 3H), | | |
| | 7.54-7.52 (m, 2H), 7.38-7.36 (m, 2H), 7.18-7.14 (m, 3H), | | |
| | 7.05-7.03 (m, 2H), 6.91-6.89 (m, 3H), 6.43 (m, 1H), 5.53 (d, 1H), | | |
| | 4.90 (m, 1H), 3.16 (m, 1H), 0.24 (s, 9H) | | |
| 28 | δ = 8.11 (s, 2H), 7.78-7.74 (m, 4H), 7.72-7.69 (m, 6H), | 728.33 | 727.27 |
| | 7.66-7.64 (m, 2H), 7.59 (s, 2H), 7.57-7.53 (m, 6H), 7.45 (s, 2H), | | |
| | 7.41-7.38 (m, 2H), 7.34-7.30 (m, 6H), 7.26-7.22 (m, 3H), | | |
| | 7.18-7.17 (dd, 2H) | | |
| 31 | δ = 8.11 (s, 2H), 7.71-7.65 (m, 12H), 7.59-7.57 (ss, 2H), | 780.41. | 779.30 |
| | 7.52 (t, 1H), 7.46-7.39 (m, 8H), 7.34-7.30 (m, 6H), 7.26-7.22 (m, | | |
| | 3H), 7.12-7.06 (m, 2H), 6.80 (d, 2H), 6.66-6.62 (m, 1H), | | |
| | 6.27-6.23 (m, 2H) | | |
| 34 | δ = 8.23-8.20 (m, 1H), 8.14 (s, 2H), 7.83-7.81 (ss, 2H), | 683.43 | 682.28 |
| | 7.70-7.67 (m, 2H), 7.62-7.60 (ss, 2H), 7.57-7.55 (m, 2H), | | |
| | 7.50-7.49 (m, 4H), 7.45 (s, 2H), 7.40-7.23 (m, 6H), 7.11-7.06 (m, | | |
| | 2H), 6.71-6.63 (m, 2H), 6.28-6.24 (m, 2H), 0.36-0.34 (s, 9H) | | |
| 36 | δ = 8.29 (s, 2H), 8.23-8.20 (m, 1H), 7.83-7.81 (ss, 2H), | 616.35 | 615.27 |
| | 7.62-7.60 (ss, 2H), 7.51-7.49 (m, 4H), 7.45 (s, 2H), 7.40-7.23 (m, | | |
| | 6H), 7.11-7.06 (m, 2H), 6.71-6.63 (m, 2H), 6.28-6.24 (m, 2H) | | |
| 38 | δ = 8.49 (s, 2H), 7.92-7.90 (ss, 2H), 7.79-7.74 (m, 7H), | 698.45 | 697.28 |
| | 7.69-7.66 (m, 4H), 7.62-7.60 (ss, 2H), 7.57-7.53 (m, 6H), | | |
| | 7.49-7.38 (m, 10H), 7.18-7.15 (dd, 2H) | | |
| 42 | δ = 8.33 (s, 2H), 8.24-8.20 (m, 2H), 7.84-7.82 (ss, 2H), | 727.42 | 726.30 |
| | 7.77-7.75 (m, 2H), 7.72 (s, 1H), 7.62-7.60 (m, 3H), 7.54-7.47 (m, | | |
| | 4H), 7.42 (s, 2H), 7.37-7.27 (m, 4H), 7.21-7.19 (m, 1H), | | |
| | 7.14-7.06 (m, 4H), 6.67-6.63 (m, 2H), 6.48 (d, 1H), | | |
| | 6.21-6.18 (m, 2H), 1.61 (s, 6H) | | |
| 46 | δ = 8.28 (s, 2H), 8.12-8.10 (m, 2H), 7.83-7.81 (ss, 2H), | 727.45 | 726.30 |
| | 7.78-7.76 (m, 1H), 7.62-7.52 (m, 5H), 7.42 (s, 2H), 7.37-7.25 (m, | | |
| | 9H), 7.14-7.06 (m. 4H), 6.67-6.63 (m, 2H), 6.48-6.47 (d, 1H), | | |
| | 6.21-6.18 (m, 2H), 1.61 (s, 6H) | | |
| 47 | δ = 8.28 (s, 2H), 8.12-8.10 (m, 2H), 7.83-7.81 (ss, 2H), | 616.44 | 615.27 |
| | 7.62-7.60 (ss, 2H), 7.55-7.52 (m, 2H), 7.40 (s, 2H), 7.37-7.35 (m, | | |
| | 8H), 7.10-7.05 (m, 2H), 6.66-6.63 (m, 1H), 6.17-6.13 (m, 2H) | | |
| 50 | δ = 8.20 (s, 2H), 7.91-7.89 (m, 2H), 7.85-7.82 (ss, 2H), | 748.43 | 747.28 |
| | 7.74-7.70 (m, 6H), 7.65-7.61 (m, 3H), 7.57-7.50 (m, 6H), | | |
| | 7.44-7.32 (m, 5H), 7.16-7.13 (dd, 1H), 7.07-7.04 (m, 2H), | | |
| | 6.63-6.60 (m, 1H), 6.08-6.05 (m, 2H), 0.50-0.48 (s, 6H) | | |
| 53 | δ = 8.23-8.20 (m, 3H), 7.91-7.88 (m, 2H), 7.84-7.82 (ss, 2H), | 743.40 | 742.28 |
| | 7.74-7.69 (m, 2H), 7.62-7.60 (ss, 2H), 7.57-7.55 (m, 1H), | | |
| | 7.50-7.49 (m, 4H), 7.45 (s, 2H), 7.40-7.23 (m, 8H), | | |
| | 7.11-7.06 (m, 2H), 6.71-6.62 (m, 2H), 6.27-6.24 (m, 2H), 0.50-0.48 (s, | | |
| | 6H) | | |
| 54 | δ = 8.28 (s, 2H), 7.99-7.95 (m, 2H), 7.84-7.82 (ss, 2H), | 752.39 | 751.27 |
| | 7.78-7.68 (m, 4H), 7.63-7.54 (m, 10H), 7.44 (s, 2H), 7.37-7.24 (m, | | |
| | 9H), 7.13-7.06 (m, 3H), 6.66-6.63 (m, 1H), 6.19-6.17 (m, 2H) | | |
| 56 | δ = 8.37 (s, 2H), 8.24-8.22 (m, 3H), 8.02-7.85 (m, 8H), | 716.52 | 715.31 |
| | 7.62-7.58 (m, 1H), 7.53-7.49 (m, 3H), 7.40-7.36 (m, 4H), | | |
| | 6.60-6.56 (m, 6H), 0.25-0.23 (s, 18H) | | |
| 57 | δ = 8.59-8.57 (m, 1H), 8.47 (d, 1H), 8.37 (s, 2H), | 672.33 | 671.26 |
| | 8.26-8.24 (m, 3H), 8.21 (d, 1H), 8.19 (s, 2H), 8.00 (s, 2H), | | |
| | 7.97-7.92 (m, 5H), 7.87-7.85 (m, 1H), 7.75-7.67 (m, 2H), 7.61-7.49 (m, | | |
| | 4H), 7.43-7.39 (m, 1H), 7.23-7.19 (m, 3H), 6.92-6.88 (m, | | |
| | 1H), 6.77-6.75 (ss, 1H), 6.58-6.55 (m, 2H) | | |
| 60 | δ = 8.65 (m, 1H), 8.55-8.53 (m, 3H), 8.40 (s, 2H), | 775.41 | 774.30 |
| | 8.22-8.17 (m, 4H), 8.10 (m, 1H), 7.90 (s, 1H), 7.86-7.79 (m, 2H), | | |
| | 7.68-7.59 (m, 7H), 7.53-7.47 (m, 9H), 7.42-7.38 (m, 2H), | | |
| | 7.18-7.14 (m, 1H), 7.09-7.07 (dd, 1H), 6.75-6.71 (m, 4H) | | |
| 62 | δ = 8.41 (s, 2H), 8.33 (s, 2H), 8.14-8.06 (m, 6H), | 752.33 | 751.23 |
| | 8.02-7.93 (m, 8H), 7.86-7.85 (dd, 1H), 7.78-7.76 (m, 1H), 7.72-7.70 (ss, | | |
| | 1H), 7.12-7.04 (m, 5H), 6.94-6.91 (dd, 1H), 6.66-6.63 (m, | | |
| | 2H), 6.33-6.29 (m, 4H) | | |
| 63 | δ = 8.33 (s, 2H), 8.22 (s, 2H), 8.17-8.08 (m, 5H), | 696.36 | 695.26 |
| | 8.02-7.93 (m, 8H), 7.86-7.85 (m, 1H), 7.72-7.70 (ss, 1H), 7.52-7.40 (m, | | |
| | 5H), 7.25-7.21 (t, 1H), 7.06-7.01 (m, 2H), 6.86-6.82 (m, 2H), | | |
| | 6.74-6.72 (m, 1H), 6.65-6.61 (m, 1H), 6.07-6.05 (m, 3H) | | |
| 64 | δ = 8.42 (s, 2H), 8.33 (s, 2H), 8.14-8.08 (m, 5H), | 736.45 | 735.26 |
| | 8.02-7.93 (m, 9H), 7.80-7.78 (d, 1H), 7.71 (m, 2H), 7.09-7.04 (m, 4H), | | |
| | 6.98 (m, 1H), 6.89-6.87 (dd, 1H), 6.66-6.63 (m, 2H), | | |
| | 6.30-6.27 (m, 4H) | | |
| 68 | δ = 8.03-8.01 (m, 2H), 7.96-7.94 (dd, 1H), 7.90-7.85 (dd, | 760.85 | 759.93 |
| | 3H), 7.75-7.71 (m, 2H), 7.64-7.60 (m, 3H), 7.46-7.35 (m, | | |
| | 6H), 7.21-7.10 (m, 6H), 7.07-7.02 (m, 4H), 6.79-6.74 (m, | | |
| | 3H), 6.63-6.59 (m, 3H), 6.04-6.01 (m, 4H) | | |
| 71 | δ = 8.33 (s, 2H), 8.31 (s, 2H), 8.24-8.21 (m, 2H), | 763.41 | 762.30 |
| | 7.98-7.92 (m, 4H), 7.83-7.70 (m, 4H), 7.65-7.62 (m, 2H), 7.51-7.44 (m, | | |
| | 6H), 7.37-7.21 (m, 3H), 7.21-7.19 (m, 1H), 7.08-7.03 (m, | | |
| | 4H), 6.86-6.82 (m, 2H), 6.66-6.63 (m, 2H), 6.16-6.13 (m, 4H) | | |
| 73 | δ = 8.28 (s, 2H), 8.12-8.10 (m, 4H), 7.86-7.83 (m, 2H), | 702.25 | 701.25 |
| | 7.75 (s, 1H), 7.72-7.69 (m, 7H), 7.56-7.52 (m, 2H), 7.35-7.22 (m, | | |
| | 17H) | | |

### Example 1

To manufacture an anode, a corning 15 Ω/cm2 (1200 Å) ITO glass substrate was cut to a size of 50 mm×50 mm×0.7 mm and then sonicated in isopropyl alcohol and pure water each for five minutes, and then cleaned by irradiation of ultraviolet rays for 30 minutes and exposure to ozone. The resulting glass substrate was loaded into a vacuum deposition device.

4,4′,4″-Tris(N-(2-naphthyl)-N-phenyl-amino)-triphenylamine (hereinafter, 2-TNATA), was vacuum-deposited on the anode to a thickness of 600 Å to form an HIL, and N,N′-bis[N-(1-naphthyl)-N-phenylamino]biphenyl (hereinafter, NPB) as a known hole transporting compound was vacuum-deposited on the HIL to a thickness of 300 Å to form a HTL.

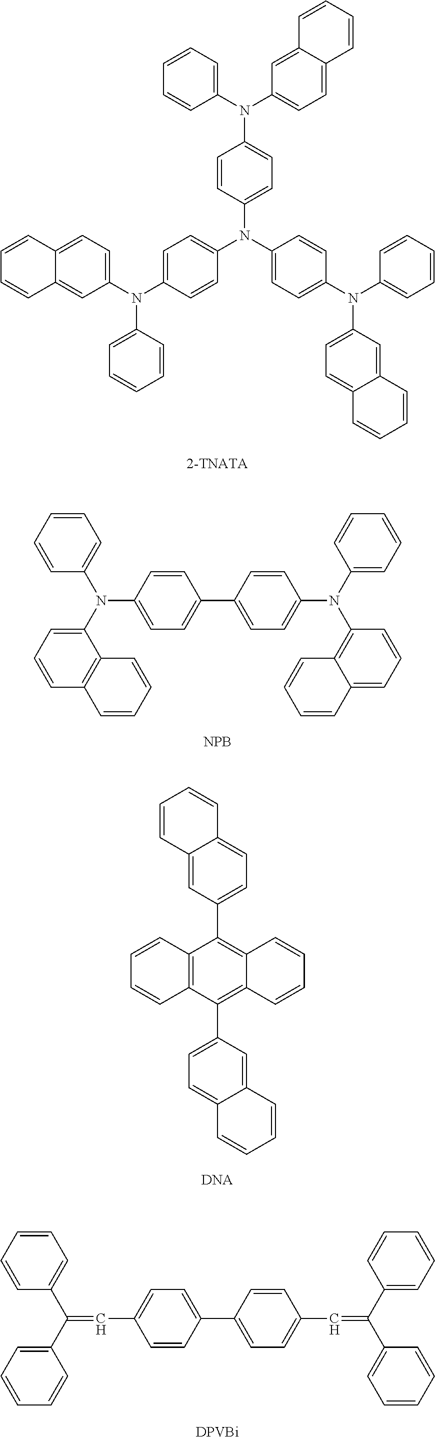

9,10-Di-naphthalene-2-yl-anthracene (hereinafter, DNA) as a blue fluorescent host, and Compound 12 as a blue fluorescent dopant, were co-deposited in a weight ratio of about 98:2 on the HTL to form an EML having a thickness of about 300 Å.

Then, Alq₃ was deposited on the EML to form an ETL having a thickness of 300 Å, and then LiF, which is a halogenated alkali metal, was deposited on the ETL to form an EIL having a thickness of 10 Å. Then, Al was vacuum-deposited on the EIL to form a cathode having a thickness of 3000 Å, thereby forming an LiF/Al electrode and completing the manufacture of an organic light-emitting device.

The organic light-emitting device had a driving voltage of about 6.84 V at a current density of 50 mA/cm², a luminosity of 2,880 cd/m², a luminescent efficiency of 5.76 cd/A, and a half life-span (hr @100 mA/cm²) of about 264 hours.

### Example 2

An organic light-emitting device was manufactured in the same manner as in Example 1, except that Compound 21 was used, instead of Compound 12, to form the EML.

The organic light-emitting device had a driving voltage of about 6.70 V at a current density of 50 mA/cm², a luminosity of 2,987 cd/m², a luminescent efficiency of 5.97 cd/A, and a half life-span (hr @100 mA/cm²) of about 271 hours.

### Example 3

An organic light-emitting device was manufactured in the same manner as in Example 1, except that Compound 28 was used, instead of Compound 12, to form the EML.

The organic light-emitting device had a driving voltage of about 6.85 V at a current density of 50 mA/cm², a luminosity of 2,794 cd/m², a luminescent efficiency of 5.58 cd/A, and a half life-span (hr @100 mA/cm²) of about 273 hours.

### Example 4

An organic light-emitting device was manufactured in the same manner as in Example 1, except that Compound 42 was used, instead of NPB as a hole transporting compound.

The organic light-emitting device had a driving voltage of about 6.22 V at a current density of 50 mA/cm², a luminosity of 2,250 cd/m², a luminescent efficiency of 4.50 cd/A, and a half life-span (hr @100 mA/cm²) of about 293 hours.

### Example 5

An organic light-emitting device was manufactured in the same manner as in Example 1, except that Compound 46 was used, instead of NPB as a hole transporting compound.

The organic light-emitting device had a driving voltage of about 6.31 V at a current density of 50 mA/cm², a luminosity of 2,147 cd/m², a luminescent efficiency of 4.29 cd/A, and a half life-span (hr @100 mA/cm²) of about 302 hours.

### Example 6

An organic light-emitting device was manufactured in the same manner as in Example 1, except that Compound 53 was used, instead of NPB as a hole transporting compound.

The organic light-emitting device had a driving voltage of about 6.35 V at a current density of 50 mA/cm², a luminosity of 2,247 cd/m², a luminescent efficiency of 4.49 cd/A, and a half life-span (hr @100 mA/cm²) of about 315 hours.

### Example 7

An organic light-emitting device was manufactured in the same manner as in Example 1, except that Compound 54 was used, instead of Compound 12, to form the EML.

The organic light-emitting device had a driving voltage of about 6.73 V at a current density of 50 mA/cm², a luminosity of 2,877 cd/m², a luminescent efficiency of 5.75 cd/A, and a half life-span (hr @100 mA/cm²) of about 213 hours.

### Example 8

An organic light-emitting device was manufactured in the same manner as in Example 1, except that Compound 56 was used, instead of Compound 12, to form the EML.

The organic light-emitting device had a driving voltage of about 6.81 V at a current density of 50 mA/cm², a luminosity of 2,821 cd/m², a luminescent efficiency of 5.64 cd/A, and a half life-span (hr @100 mA/cm²) of about 224 hours.

### Example 9

An organic light-emitting device was manufactured in the same manner as in Example 1, except that Compound 68 was used, instead of NPB as a hole transporting compound.

The organic light-emitting device had a driving voltage of about 6.18 V at a current density of 50 mA/cm², a luminosity of 2,474 cd/m², a luminescent efficiency of 4.94 cd/A, and a half life-span (hr @100 mA/cm²) of about 351 hours.

### Example 10

An organic light-emitting device was manufactured in the same manner as in Example 1, except that Compound 68 was used, instead of NPB as a hole transporting compound, and Compound 21 was used, instead of Compound 12, to form the EML.

The organic light-emitting device had a driving voltage of about 6.15 V at a current density of 50 mA/cm², a luminosity of 3,012 cd/m², a luminescent efficiency of 6.02 cd/A, and a half life-span (hr @100 mA/cm²) of about 362 hours.

### Comparative Example 1

An organic light-emitting device was manufactured in the same manner as in Example 1, except that DPVBi was used, instead of Compound 12, to form the EML.

The organic light-emitting device had a driving voltage of about 7.35 V at a current density of 50 mA/cm², a luminosity of 2,065 cd/m², a luminescent efficiency of 4.13 cd/A, and a half life-span (hr @100 mA/cm²) of about 145 hours.

### Comparative Example 2

An organic light-emitting device was manufactured in the same manner as in Example 1, except that (9)-30 was used, instead of Compound 12, to form the EML.

The organic light-emitting device had a driving voltage of about 7.65 V at a current density of 50 mA/cm², a luminosity of 2,184 cd/m², a luminescent efficiency of 4.36 cd/A, and a half life-span (hr @100 mA/cm²) of about 142 hours.

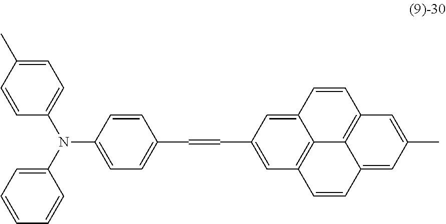 [SMILES: Cc1ccc(N(c2ccccc2)c2ccc(C=Cc3cc4ccc5cc(C)cc6ccc(c3)c4c56)cc2)cc1]

### Comparative Example 3

An organic light-emitting device was manufactured in the same manner as in Example 1, except that D-102 was used, instead of Compound 12, to form the EML.

The organic light-emitting device had a driving voltage of about 7.25 V at a current density of 50 mA/cm², a luminosity of 2,056 cd/m², a luminescent efficiency of 4.11 cd/A, and a half life-span (hr @100 mA/cm²) of about 130 hours.

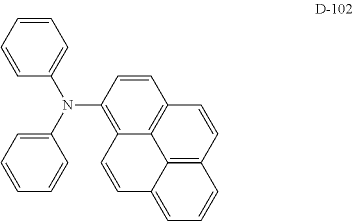 [SMILES: c1ccc(N(c2ccccc2)c2ccc3ccc4cccc5ccc2c3c45)cc1]

The characteristics of the organic light-emitting devices of Examples 1-10 and Comparative Examples 1-3 are shown in Table 2 below.

TABLE 2

| | HTL or | Driving | Current | | | | |
|---|---|---|---|---|---|---|---|
| | dopant | voltage | density | Luminance | Efficiency | Emission | Half-life span |
| | material | (V) | (mA/cm²) | (cd/m²) | (cd/A) | Color | (hr @100 mA/cm²) |
| Example 1 | Compound 12 | 6.84 | 50 | 2,880 | 5.76 | Blue | 264 hr |
| Example 2 | Compound 21 | 6.70 | 50 | 2,987 | 5.97 | Blue | 271 hr |
| Example 3 | Compound 28 | 6.85 | 50 | 2,794 | 5.58 | Blue | 273 hr |
| Example 4 | Compound 42 | 6.22 | 50 | 2,250 | 4.50 | Blue | 293 hr |
| Example 5 | Compound 46 | 6.31 | 50 | 2,147 | 4.29 | Blue | 302 hr |
| Example 6 | Compound 53 | 6.35 | 50 | 2,247 | 4.49 | Blue | 315 hr |
| Example 7 | Compound 54 | 6.73 | 50 | 2,877 | 5.75 | Blue | 213 hr |
| Example 8 | Compound 56 | 6.81 | 50 | 2,821 | 5.64 | Blue | 224 hr |
| Example 9 | Compound 68 | 6.18 | 50 | 2,474 | 4.94 | Blue | 351 hr |
| Example 10 | Compound 68 | 6.15 | 50 | 3,012 | 6.02 | Blue | 362 hr |
| | Compound 21 | | | | | | |
| Comparative | DPVBi | 7.35 | 50 | 2,065 | 4.13 | Blue | 145 hr |
| Example 1 | | | | | | | |
| Comparative | (9)-30 | 7.65 | 50 | 2,184 | 4.36 | Blue | 142 hr |
| Example 2 | | | | | | | |
| Comparative | D-102 | 7.25 | 50 | 2,056 | 4.11 | Blue | 130 hr |
| Example 3 | | | | | | | |

The organic light-emitting devices manufactured using the compounds represented by Formula 1 according to embodiments as HTL materials had significantly lower driving voltages and improved I-V-L characteristics. In particular, the organic light-emitting devices of Examples 1-10 had markedly improved lifetimes compared to Comparative Examples 1-3.

As described above, according to the one or more of the above embodiments of the present invention, an organic light-emitting device including the compound of Formula 1 has high efficiency, high luminance, and long lifetime.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light-emitting device comprising:
a first electrode;
a second electrode; and
an organic layer disposed between the first electrode and the second electrode,
wherein the organic layer comprises an emission layer and/or a hole transport layer, wherein the emission layer and/or hole transport layer comprises a compound represented by Formula 1 below: 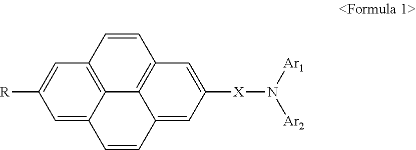
wherein, in Formula 1, R is —CN, a halogen atom, —SiR₁R₂R₃, —OR₁, —SR₁, —PR₁R₂, a substituted or unsubstituted C1-C60 alkyl group, a substituted or unsubstituted C3-C60 heteroaryl group, a substituted or unsubstituted C6-C60 aryl group, or a substituted or unsubstituted C6-C60 condensed polycyclic group; R₁ to R₃ are each independently a substituted or unsubstituted C1-C30 alkyl group, a substituted or unsubstituted C6-C30 aryl group, a substituted or unsubstituted C6-C30 condensed polycyclic group; Ar₁ to Ar₂ are each independently a substituted or unsubstituted C5-C60 aryl group, a substituted or unsubstituted C4-C60 heteroaryl group, or a substituted or unsubstituted C6-C60 condensed polycyclic group; and X is a direct bond, a substituted or unsubstituted C5-C60 arylene group, a substituted or unsubstituted C4-C60 heteroarylene group, a substituted or unsubstituted C6-C60 condensed polycyclic group, or a group formed by linking at least two of the arylene groups, the heteroarylene groups, or the condensed polycyclic groups.

2. The organic light-emitting device of claim 1, wherein, in Formula 1, R is one of the groups represented by Formulae 2a to 2f below: 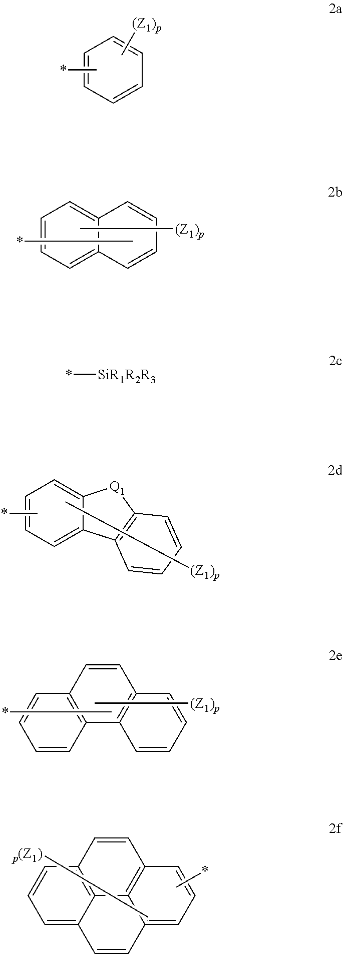
wherein, in Formulae 2a to 2f, Q₁ is represented by —C(R₃₀)(R₃₁)—, —N(R₃₂)—, or —Si(R₃₃)(R₃₄)—; Z₁ and R₃₀ to R₃₄ are each independently the same or different within each formula and across formulas, a hydrogen atom, a deuterium atom, a substituted or unsubstituted C1-C20 alkyl group, a substituted or unsubstituted C5-C20 aryl group, a substituted or unsubstituted C3-C20 heteroaryl group, or a substituted or unsubstituted C6-C20 condensed polycyclic group, a halogen group, a cyano group, a nitro group, a hydroxyl group, or a carboxyl group; R₁ to R₃ are each independently a substituted or unsubstituted C1-C30 alkyl group, a substituted or unsubstituted C6-C30 aryl group, or a substituted, or unsubstituted C6-C30 condensed polycyclic group; p is an integer from 1 to 9; and * represents a binding site.

3. The organic light-emitting device of claim 2, wherein R₃₀ and R₃₁ are linked to form a ring.

4. The organic light-emitting device of claim 1, wherein, in Formula 1, Ar₁ and Ar₂ are one of the groups represented by Formulae 3a to 3e below: 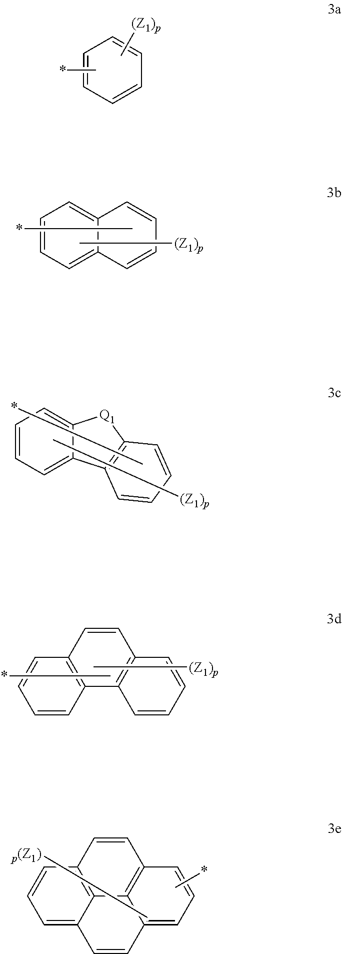
wherein, in Formulae 3a to 3e, Q₂ is represented by —C(R₃₀)(R₃₁)—, —N(R₃₂)—, or —Si(R₃₃)(R₃₄)—; Z₁, R₃₀ to R₃₄ are each independently, the same or different within each formula and across formulas, a hydrogen atom, a deuterium atom, —SiR₁R₂R₃, a substituted or unsubstituted C1-C20 alkyl group, a substituted or unsubstituted C5-C20 aryl group, a substituted or unsubstituted C3-C20 heteroaryl group, a substituted or unsubstituted C6-C20 condensed polycyclic group, a halogen group, a cyano group, a nitro group, a hydroxyl group, or a carboxyl group; R₁ to R₃ are each independently a substituted or unsubstituted C1-C30 alkyl group, a substituted or unsubstituted C6-C30 aryl group, or a substituted, or unsubstituted C6-C30 condensed polycyclic group; p is an integer from 1 to 9; and * represents a binding site.

5. The organic light-emitting device of claim 4, wherein R₃₀ and R₃₁ are linked to form a ring.

6. The organic light-emitting device of claim 1, wherein, in Formula 1, X is a single bond or one of the groups represented by Formulae 4a to 4d below: 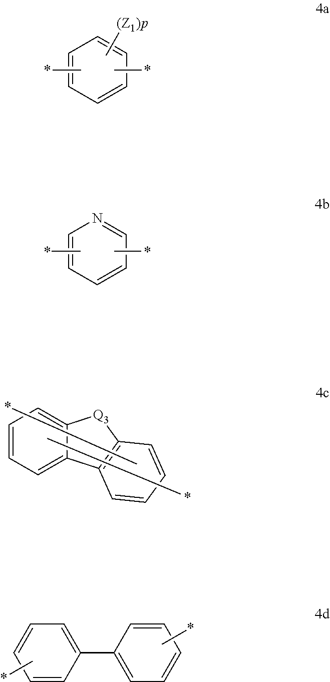
wherein, in Formulae 4a to 4d, Q₃ is represented by —C(R₃₀)(R₃₁)—, —S—, or —O—; Z₁, R₃₀, and R₃₁ are each independently, a hydrogen atom, a deuterium atom, a substituted or unsubstituted C1-C20 alkyl group, a substituted or unsubstituted C5-C20 aryl group, a substituted or unsubstituted C3-C20 heteroaryl group, a substituted or unsubstituted C6-C20 condensed polycyclic group, a halogen group, a cyano group, a nitro group, a hydroxyl group, or a carboxyl group; p is an integer from 1 to 4; and * represents a binding site.

7. The organic light-emitting device of claim 1, wherein the compound of Formula 1 is one of the following compounds:

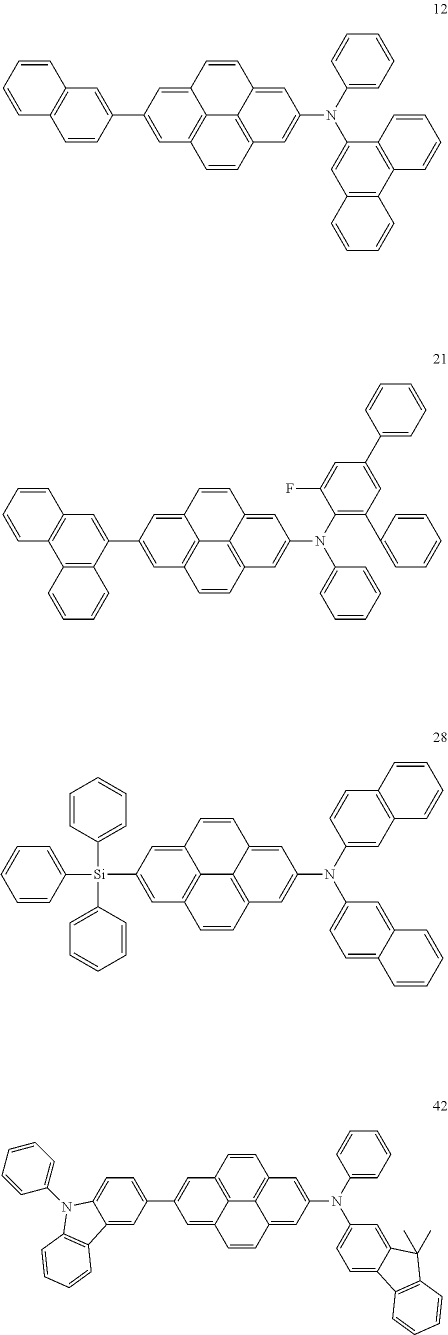 [SMILES: c1ccc(N(c2cc3ccc4cc(-c5ccc6ccccc6c5)cc5ccc(c2)c3c45)c2cc3ccccc3c3ccccc23)cc1 ; Fc1cc(-c2ccccc2)cc(-c2ccccc2)c1N(c1ccccc1)c1cc2ccc3cc(-c4cc5ccccc5c5ccccc45)cc4ccc(c1)c2c34 ; c1ccc([Si](c2ccccc2)(c2ccccc2)c2cc3ccc4cc(N(c5ccc6ccccc6c5)c5ccc6ccccc6c5)cc5ccc(c2)c3c45)cc1 ; CC1(C)c2ccccc2-c2ccc(N(c3ccccc3)c3cc4ccc5cc(-c6ccc7c(c6)c6ccccc6n7-c6ccccc6)cc6ccc(c3)c4c56)cc21]

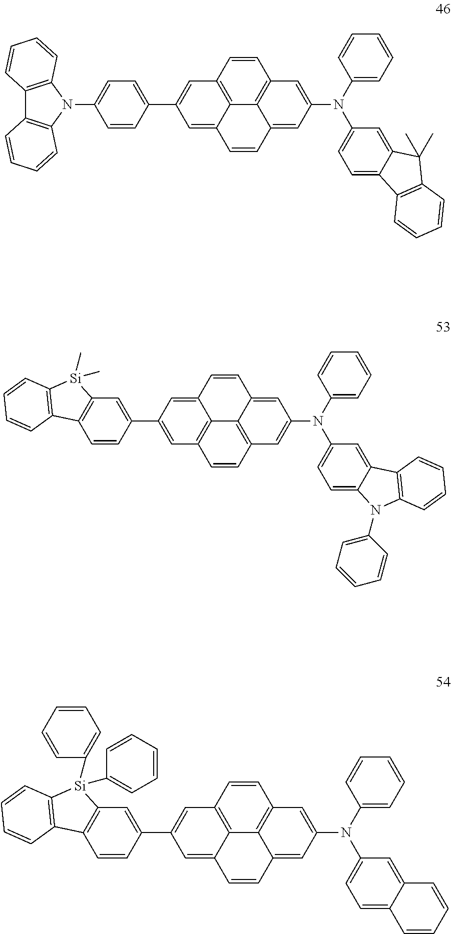 [SMILES: CC1(C)c2ccccc2-c2ccc(N(c3ccccc3)c3cc4ccc5cc(-c6ccc(-n7c8ccccc8c8ccccc87)cc6)cc6ccc(c3)c4c56)cc21 ; C[Si]1(C)c2ccccc2-c2ccc(-c3cc4ccc5cc(N(c6ccccc6)c6ccc7c(c6)c6ccccc6n7-c6ccccc6)cc6ccc(c3)c4c56)cc21 ; c1ccc(N(c2ccc3ccccc3c2)c2cc3ccc4cc(-c5ccc6c(c5)[Si](c5ccccc5)(c5ccccc5)c5ccccc5-6)cc5ccc(c2)c3c45)cc1]

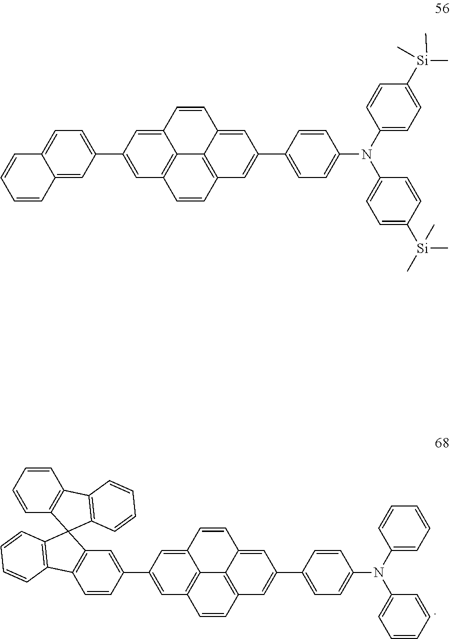 [SMILES: C[Si](C)(C)c1ccc(N(c2ccc(-c3cc4ccc5cc(-c6ccc7ccccc7c6)cc6ccc(c3)c4c56)cc2)c2ccc([Si](C)(C)C)cc2)cc1 ; c1ccc(N(c2ccccc2)c2ccc(-c3cc4ccc5cc(-c6ccc7c(c6)C6(c8ccccc8-c8ccccc86)c6ccccc6-7)cc6ccc(c3)c4c56)cc2)cc1]

8. The organic light-emitting device of claim 1, wherein the emission layer is a blue emission layer.

9. The organic light-emitting device of claim 1, wherein the organic light-emitting device comprises an emission layer, an electron injection layer, an electron transport layer, a functional layer having both electron injection and transport capabilities, a hole injection layer, a hole transport layer, or a functional layer having both hole injection and transport capabilities; wherein the emission layer further comprises an anthracene-based compound, an arylamine-based compound, or a styryl-based compound.

10. The organic light-emitting device of claim 1, wherein the organic light-emitting device comprises an emission layer, an electron injection layer, an electron transport layer, a functional layer having both electron injection and transport capabilities, a hole injection layer, a hole transport layer, or a functional layer having both hole injection and transport capabilities; wherein the emission layer comprises red, green, blue, and white emission layers one or more of which comprises a phosphorescent compound.

11. The organic light-emitting device of claim 10, wherein the hole injection layer, the hole transport layer, or the functional layer having both hole injection and hole transport capabilities comprises a charge-generating material.

12. The organic light-emitting device of claim 11, wherein the charge-generating material is a p-dopant.

13. The organic light-emitting device of claim 12, wherein the p-dopant is a quinone derivative.

14. The organic light-emitting device of claim 12, wherein the p-dopant is a metal oxide.

15. The organic light-emitting device of claim 12, wherein the p-dopant is a cyano group-containing compound.

16. The organic light-emitting device of claim 1, wherein the organic layer comprises an electron transport layer, and the electron transport layer further comprises a metal complex.

17. The organic light-emitting device of claim 16, wherein the metal complex is a lithium complex.

18. The organic light-emitting device of claim 16, wherein the metal complex is Compound 203 below:

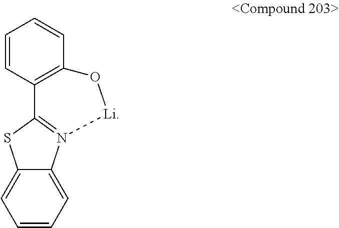

19. The organic light-emitting device of claim 1, wherein the organic layer comprising the compound of Formula 1 is formed using a wet process.

20. A flat panel display device comprising the organic light-emitting device of claim 1, wherein the first electrode of the organic light-emitting device is electrically connected to a source electrode or a drain electrode of a thin-film transistor.
